(19) United States
(12) Patent Application Publication
(10) Pub. No.: US 2026/0010684 A1
(43) Pub. Date: Jan. 8, 2026

(54) SIMULATION APPARATUS, RECORDING MEDIUM, AND SIMULATION METHOD

(71) Applicant: ROHM CO., LTD., Kyoto-shi (JP)

(72) Inventors: Kenji HAMACHI, Kyoto-shi (JP); Koji TAMANO, Kyoto-shi (JP)

(21) Appl. No.: 19/250,315

(22) Filed: Jun. 26, 2025

(30) Foreign Application Priority Data
Jul. 3, 2024 (JP) 2024-107468

(51) Int. Cl. G06F 30/27; G06F 30/17

(52) U.S. Cl. CPC G06F 30/27; G06F 30/17

(57) ABSTRACT

In the simulation apparatus, a model setting unit executes setting related to a chunk as a batch block of data in a case where data are sequentially entered into a machine learning model on a basis of loaded data. A model computing unit executes computations of unsupervised training and computations of prediction by sequentially entering the chunk into the machine learning model. A model storage unit is configured to non-temporarily store not only the machine learning model before execution of the computations of training but also the machine learning model after execution of at least part of the computations of training.

### CROSS REFERENCE TO RELATED APPLICATIONS

The present invention claims priority under 35 U.S.C. § 119 on Japanese Patent Application No. 2024-107468 filed Jul. 3, 2024, the entire contents of which are hereby incorporated by reference.

### BACKGROUND OF THE INVENTION

### 1. Technical Field

The present disclosure relates to a simulation apparatus, a recording medium, and a simulation method.

### 2. Description of Related Art

Conventionally, AI (Artificial Intelligence) is increasingly employed in condition-based maintenance of a mechanical system for the maintenance of factory equipment in industrial fields (e.g., WO 2019/035279).

### BRIEF DESCRIPTION OF THE DRAWINGS

FIG. 1 is a diagram showing the configuration of a computer according to an exemplary embodiment of the present disclosure.

FIG. 2 is a diagram showing the configuration of a simulation apparatus according to the exemplary embodiment of the disclosure.

FIG. 3 is a diagram showing a configuration example of a machine learning model.

FIG. 4 is a diagram showing a three-layer neural network.

FIG. 5 is a view showing a first setting screen.

FIG. 6 is a view showing a dialog box.

FIG. 7 is a view showing one example of data in a data file (sample file).

FIG. 8 is a view showing a first setting screen.

FIG. 9 is a view showing one example of preprocessing settings and processing results on Column 1 in the first setting screen.

FIG. 10 is a view showing one example of preprocessing settings and processing results on Column 2 in the first setting screen.

FIG. 11 is a view showing one example of preprocessing settings and processing results on Column 3 in the first setting screen.

FIG. 12 is a view showing one example of preprocessing settings and processing results on Column 4 in the first setting screen.

FIG. 13 is a view showing a second setting screen.

FIG. 14 is a view showing a second setting screen.

FIG. 15 is a view showing a second setting screen.

FIG. 16 is a view showing a third setting screen.

FIG. 17 is a view showing an example of preprocessing results in a third setting screen.

FIG. 18 is a view showing a training-and-prediction setting portion in a third setting screen.

FIG. 19 is a view showing an example of settings for training and prediction.

FIG. 20 is a view showing a fourth setting screen.

FIG. 21 is a view showing a fourth setting screen.

FIG. 22 is a view showing an example of repetition training.

FIG. 23 is a view showing a graph screen.

FIG. 24 is a view showing a save screen.

FIG. 25 is a view showing one example in which β and P of a machine learning model after execution of computations of training (trained machine learning model) are displayed in a matrix form.

FIG. 26 is a view showing one example in which β of the machine learning model after execution of computations of training (trained machine learning model) is displayed in a matrix form.

FIG. 27 is a view showing one example in which P of the machine learning model after execution of computations of training (trained machine learning model) is displayed in a matrix form.

### DETAILED DESCRIPTION OF PREFERRED EMBODIMENTS

Now, an exemplary embodiment of the present disclosure will be described with reference to accompanying drawings.

### <Configuration of Computer>

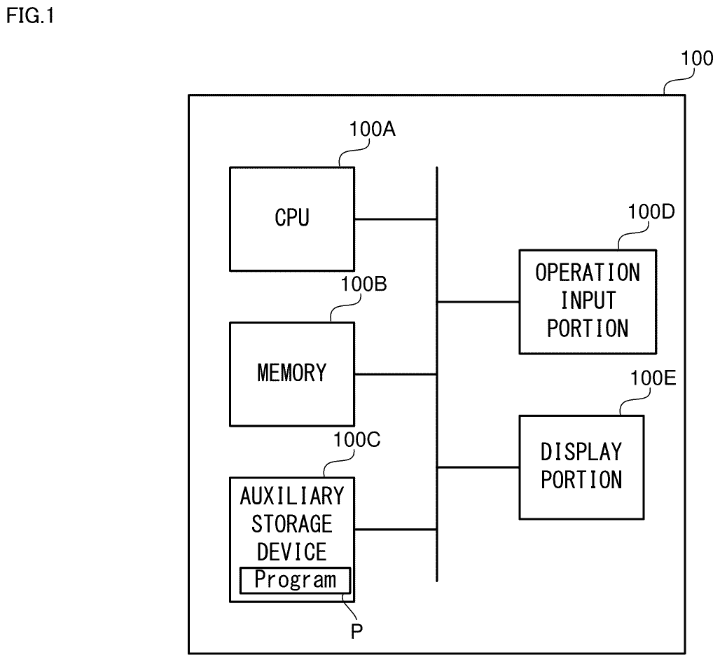

FIG. 1 is a diagram showing the configuration of a computer 100 according to an exemplary embodiment of the present disclosure. The computer 100 functions as a later-described simulation apparatus according to the present disclosure. The computer 100 is, for example, a PC (personal computer). Given a PC as the computer 100, it is no matter whether the PC is desktop type or notebook type.

The computer 100 includes a CPU (central processing unit) 100A, a memory 100B, an auxiliary storage device 100C, an operation input portion 100D, and a display portion 100E.

The CPU 100A includes a control device and a computation device (neither is shown). The control device interprets instructions in a program to control the different parts of the computer 100. The computation device executes arithmetic operations.

The memory 100B is a semiconductor storage device that temporarily stores a program or data. The information stored in the memory 100B is lost when the power to the computer 100 is turned off.

The auxiliary storage device 100C is configured with an HDD (hard disk drive), an SSD (solid-state drive), or the like and stores a program or data. The program stored in the auxiliary storage device 100C is read into the memory 100B. The CPU 100A executes the program read into the memory 100B.

The operation input portion 100D is configured with a keyboard, a mouse, and the like and feeds the computer 100 with the input of user operations. The information input through the operation input portion 100D is fed to the memory 100B.

The display portion 100E is configured with, for example, a liquid crystal display and outputs the information acquired from the memory 100B in a form converted into an image.

### <Configuration of Simulation Apparatus>

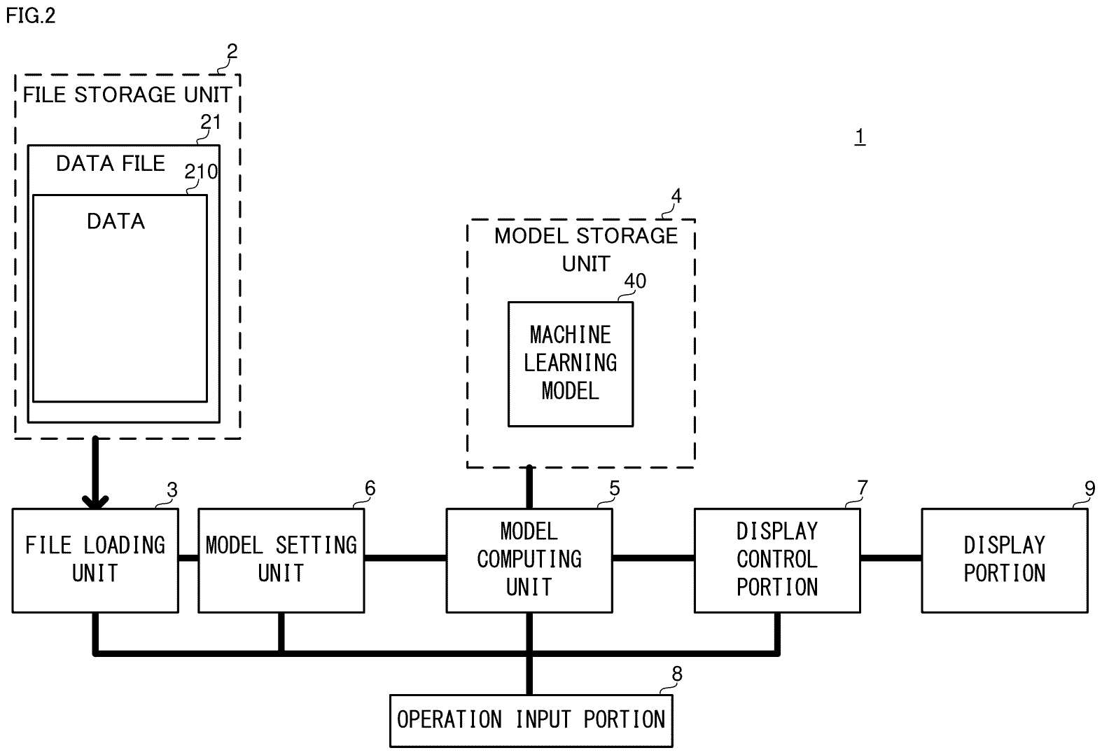

FIG. 2 is a diagram showing the configuration of a simulation apparatus 1 according to the exemplary embodiment of the disclosure. The simulation apparatus 1 is an apparatus capable of simulating training and prediction by machine training (AI).

The simulation apparatus 1 includes a file storage unit 2, a file loading unit 3, a model storage unit 4, a model computing unit 5, a model setting unit 6, a display control portion 7, an operation input portion 8, and a display portion 9.

The file storage unit 2, which stores a data file 21, is configured with an auxiliary storage device 100C of the computer 100. The data file 21 is configured as an Excel (trademark) file as an example. In addition, the file may be stored into the auxiliary storage device 100C from outside of the computer 100 via USB interface of the computer 100 or network interface (neither is shown in FIG. 1), as an example.

The data file 21 includes data 210. The data 210 is to be entered into a machine learning model 40 (described later) with an aim of executing therewith so-called unsupervised training and prediction. As will be described later, data for use in training and data for use in prediction can be designated out of the data 210.

The file loading unit 3 loads the data file 21 from the file storage unit 2.

The model storage unit 4, which has stored a machine learning model 40, is configured with the auxiliary storage device 100C of the computer 100. The machine learning model 40 is configured as part of a program P by, for example, MATLAB/Simulink (trademark). Concrete examples of the machine learning model 40 will be described later.

Individual functions of the file loading unit 3, the model computing unit 5, the model setting unit 6, and the display control portion 7 are implemented by the program P executed by the CPU 100A. In addition, the operation input portion 8 and the display portion 9 are equivalent to the operation input portion 100D and the display portion 100E, respectively, of the computer 100.

The model computing unit 5 executes a simulation by executing computing process of the machine learning model 40 stored in the model storage unit 4. The model setting unit 6, in response to inputs from the operation input portion 8, executes settings (setting of data to be used for training and prediction, setting of parameters, setting of types of functions, etc.) related to the machine learning model 40 stored in the model storage unit 4. Simulations by the model computing unit 5 are executed according to setting contents by the model setting unit 6. The display control portion 7 executes control process that allows various types of screens such as later-described setting screens to be displayed on the display portion 9 in response to inputs from the operation input portion 8.

For example, applications of machine learning are increasingly employed in condition-based maintenance of mechanical systems for the maintenance of factory equipment in industrial fields. However, even when a user tries to execute an expected AI algorithm, there is a necessity for providing data to an AI vendor or other AI developer. Since the data, in many cases, includes secret information associated with a product and its manufacturing process, it is hard to disclose the data. Therefore, it has conventionally been the only way for such a case that various cases of the AI vendor or the like are referenced, or that an open problem which has become a common benchmark for AI performance (e.g., housing price prediction in Boston, physical property estimation of diesel fuel, etc.) is given as a problem to be solved, followed by a judgment whether it is suitable as a user's problem and for problem solution. As a matter of course, such an open problem is inconsistent with a user's problem and issue. For this reason, when a selected AI algorithm is applied to user's data, there would often be the case where it proves clear a posteriori that the selected AI algorithm had been inappropriate or less appropriate. As a result of this, reselection of an AI algorithm would cause a disadvantage for both the user and the AI vendor.

As described above, event in a user's attempt to know what kind of achievements can be fulfilled by using user's acquired data, there is a need for sharing the data with outside (AI vendor or IC maker having AI solution etc.). That is, there is a risk of getting out the data, which is secret information. Also, it is a difficulty whether data, when provided alone, can be properly analyzed by outside or not; it is difficult to attain proper adjustment of AI parameters without high-level knowledge as to a domain of which data has been acquired by the user. Transmission of domain knowledge from the user to the AI vendor or the like also involves quite large time and effort, while gaps in background knowledge cause communication errors to be more likely to occur. Further, data acquired by the user cannot be analyzed on a same-day and in-place basis.

Under the above-described circumstances, using the simulation apparatus 1 according to the present disclosure makes it possible to effectively verify AI effect of unsupervised training with a user's own data. More specifically, it becomes possible to verify an effect of anomaly detection which is a task of unsupervised training. As a result of this, for example, there can be fulfilled such effects as elimination of a risk of getting out secret-information data, and practicalization of in-place analysis of acquired data. In particular, the present disclosure, as will be described later, has introduced a concept of chunk for setting of data which are to be entered into a machine learning model, facilitating such settings as entering plural types of input data on a plural-data-piece basis. This makes it implementable to discuss, for example, what types of anomaly detection are enabled on a basis of combinations among various signals.

### <Configuration of Machine Learning Model>

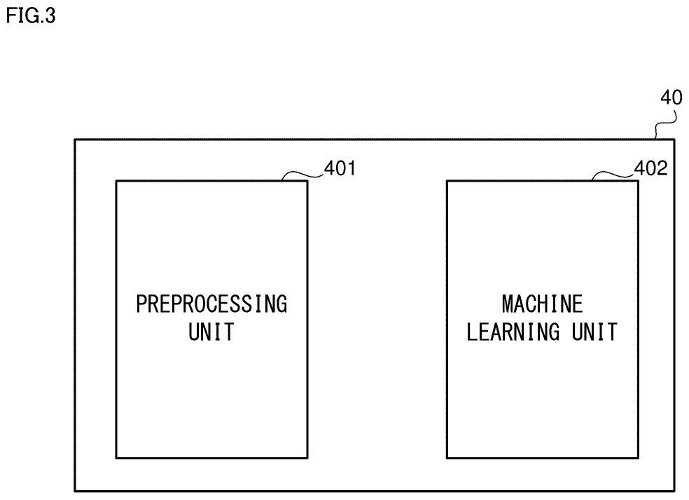

Here is given a description on the machine learning model 40. FIG. 3 is a diagram showing a configuration example of the machine learning model 40. The machine learning model 40 includes a preprocessing unit 401 and a machine learning unit 402.

The preprocessing unit 401 performs preprocessing prior to entry of data into the machine learning unit 402. The preprocessing includes normalization process. The normalization process is a process of accommodating data within a range of about 0 to 1 (or −1 to +1). As will be described later, setting parameters of the normalization process allows shifting process or no process to be set instead.

The preprocessing also includes envelope process. The envelope process is executed with data subjected to the normalization process. In addition, execution or non-execution of the envelope process is settable as will be described later.

The preprocessing further includes window function process and FFT (Fast Fourier Transform) process. As described later, the window function process and the FFT process are performed with data which has been subjected to the normalization process and the envelope process. Also, the window function process and the FFT process are performed on a chunk-by-chunk basis as described later. The window function process and the FFT process are settable in terms of execution or non-execution, respectively, as described later. Settable patterns are execution of only the window function process, execution of only the FFT process, or execution of both the window function process and the FFT process. In addition, without being limited to the FFT process, frequency analysis process such as wavelet transformation or the like may be used.

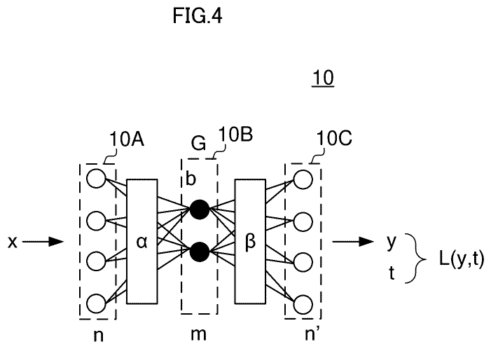

The machine learning unit 402 performs training and prediction with inputted data. For example, such a three-layer neural network 30 as shown in FIG. 4 is used as an AI model to be used in the machine learning unit 402.

As shown in FIG. 4, the three-layer neural network 10 is an AI model including an input layer 10A, a hidden layer 10B, and an output layer 10C. In the three-layer neural network 10, generally, with respect to n-dimensional input data x∈R^{k×n} having a batch size of k, an n′-dimensional prediction result y∈R^{k×n′} can be obtained as y=G(x·α+b)β. In this connection, α∈R^{n×m} is a weight that connects the input layer 10A and the hidden layer 10B to each other, and β∈R^{m×n′} is a weight that connects the hidden layer 10B and the output layer 10C to each other. Also, b∈R^{m} is a bias of the hidden layer 10B, and G is an activation function of the hidden layer 10B.

This embodiment employs algorithm that allows the three-layer neural network 10 to be trained sequentially on an arbitrary batch-size basis. When ith training data {xᵢ∈Rᵢ^{k×n}, tᵢ∈Rᵢ^{k×n′}} of the batch size kᵢ is obtained, it is necessary to determine βᵢ that minimizes an error represented by Expression (1) below.

$$‖ [ \begin{matrix}{H}_{0} \\ ⋮ \\ {H}_{i}\end{matrix} ] {β}_{i} - [ \begin{matrix}{t}_{0} \\ ⋮ \\ {t}_{i}\end{matrix} ] ‖ \qquad ( 1 )$$

It is noted that the ith hidden-layer matrix is Hᵢ=G(xᵢ·α+b). Also, t is teaching data corresponding to a prediction result y.

An optimized weight βᵢ is calculated by Expression (2) below.

$${P}_{i} = {P}_{i - 1} - {P}_{i - 1} {{H}_{i}^{T} ( I + {H}_{i} {P}_{i - 1} {H}_{i}^{T} )}^{- 1} {H}_{i} {P}_{i - 1} \qquad ( 2 )$$

$${β}_{i} = {β}_{i - 1} + {P}_{i} {H}_{i}^{T} ( {t}_{i} - {H}_{i} {β}_{i - 1} )$$

Where, P₀ and β₀ are obtained by Expression (3) below.

$${P}_{0} = {( {H}_{0}^{T} {H}_{0} )}^{- 1} \qquad ( 3 )$$

$${β}_{0} = {P}_{0} {H}_{0}^{T} {t}_{0}$$

The algorithm of training is as follows:
(1) Initialize the values of the weight α and the bias b with random numbers.
(2) Calculate H₀ for x₀, and calculate P₀ and β₀.
(3) Every time the ith training data of batch size kᵢ is obtained, calculate Pᵢ and βᵢ. Here, β₀ need not be calculated according to the equation for its calculation in Expression (3); a value initialized with a random number can be taken as β₀.

Moreover, training using an autoencoder is performed in this embodiment. An autoencoder uses input data as it is as teaching data, and trains in a way that the input data can be reconstructed as a prediction result; that is, in terms of what has been described above, it trains assuming that t=x. An autoencoder does not require separately created teaching data, hence one kind of unsupervised training algorithm.

According to such an AI model in the machine learning unit 402, training by a computing device of microcomputer-equivalent level is enabled with edge devices. The term, edge devices, refers to information processing devices which take over trained machine learning models from other devices and performs prediction computations by using trained machine learning models. That is, in a case where such on-device training is introduced for anomaly detection of motors as an example, an effect of anomaly detection can be verified by simulations. It is noted that the input data x is time-series data with no FFT process involved in the preprocessing unit 401, and frequency-region data with FFT process involved.

In the machine learning unit 402, an anomaly score is calculated by a loss function L(y,t) representing an error between a prediction result and teaching data t. The loss function employs, for example, MAE (Mean Absolute Error) or MSE (Mean Squared Error). With MAE employed for the loss function, a loss function L is expressed as Expression (4) below.

$$L ( y , t ) = \frac{1}{{n}^{′}} \sum \vert y - t \vert \qquad ( 4 )$$

Also, with MSE employed for the loss function, a loss function L is expressed as Expression (5) below.

$$L ( y , t ) = \frac{1}{{n}^{′}} \sum {\vert y - t \vert}^{2} \qquad ( 5 )$$

Since the autoencoder is employed to perform training, the anomaly score is calculated as a loss function L(y,t)=L(y,x).

### <GUI>

Next, an explanation is given on a GUI (Graphical User Interface) that enables setting related to simulations in the simulation apparatus 1 according to this embodiment. Examples of various screens described below are displayed on the display portion 9 by the display control portion 7 (FIG. 2). Selections and settings in various setting screens, switching of screens, and the like are performed based on inputs by the operation input portion 8. Contents that are set in various setting screens are set by the model setting unit 6.

### <<First Setting Screen>>

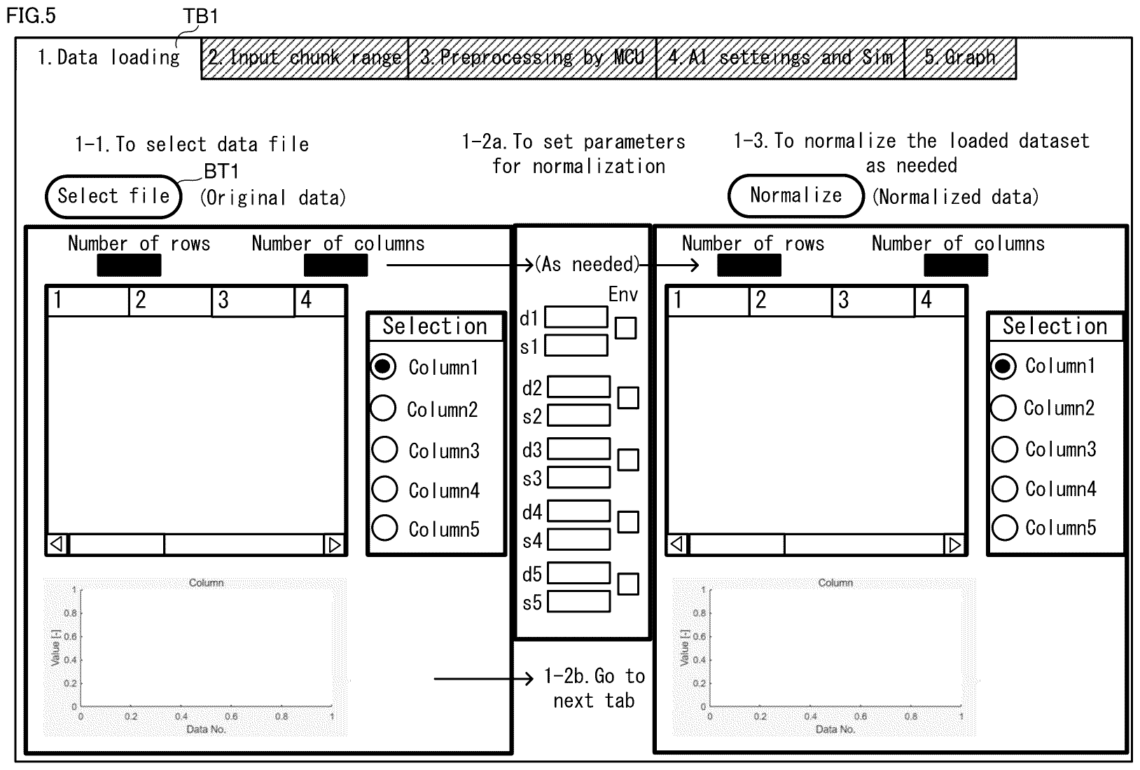

As the program P is started up, a first setting screen shown in FIG. 5 is displayed. In the first setting screen, loading of a data file and, as required, setting of preprocessing can be executed. In upper portion of the first setting screen, tabs are displayed in left-to-right array. Pressing the tabs allows the setting screen to be changed over. FIG. 5 (first setting screen) shows a state in which a tab TB1 of “1. Data loading” has been pressed.

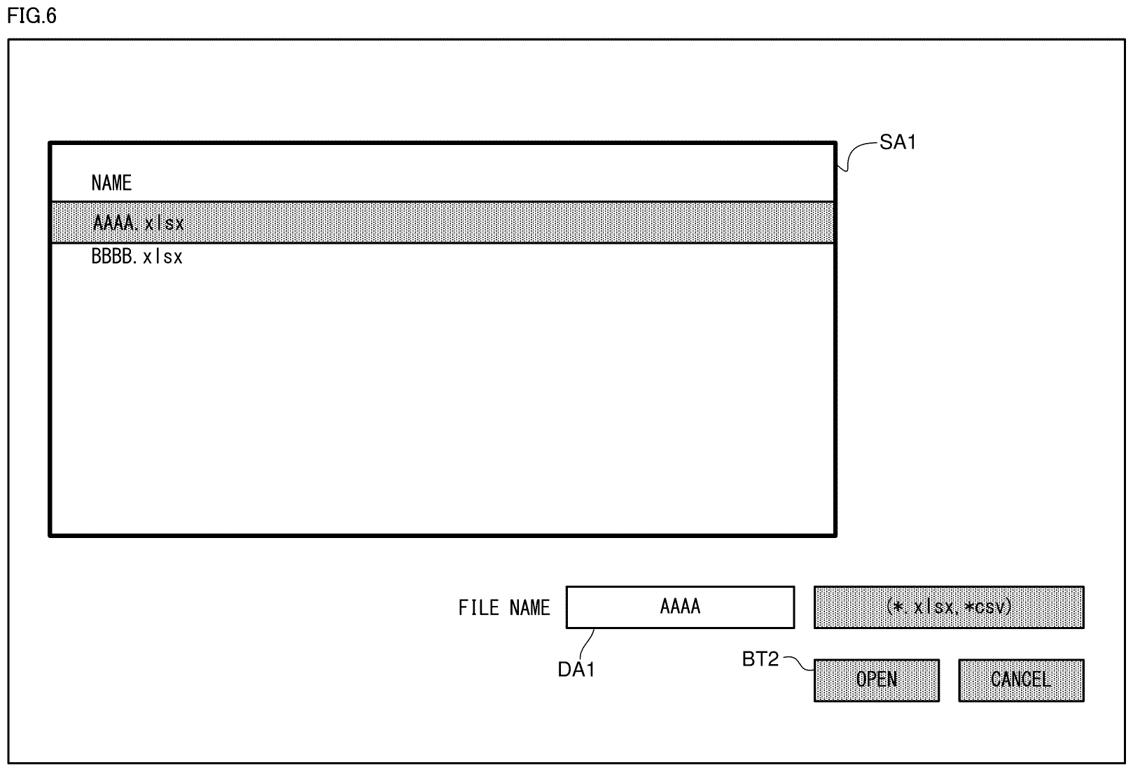

In the first setting screen, a select button BT1 for selection of a data file is displayed. Pressing the select button BT1 causes a dialog box shown in FIG. 6 to be displayed. In the dialog box, a list of file names is displayed in a selection area SA1. A file name selected in the selection area SA1 is displayed in a file-name display area DA1 given downward. When a decision button BT2 is pressed in the dialog box, a data file having the file name displayed in the file-name display area DA1 is loaded by the file loading unit 3. In this case, Excel files having an extension of xlsx are selectable.

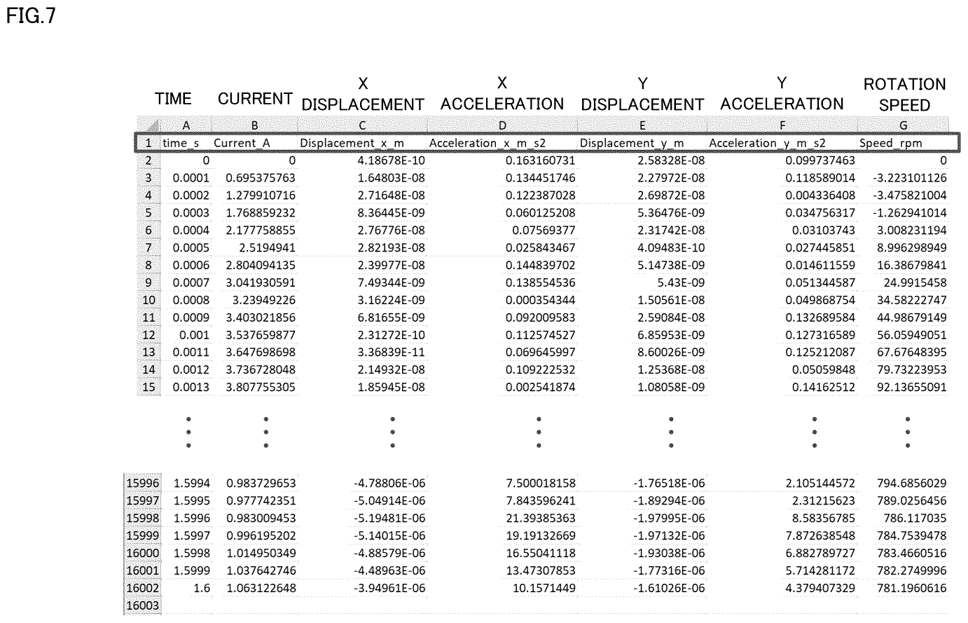

In this connection, FIG. 7 is a view showing one example of data in the data file (sample file). Data of FIG. 7 are time-series data of various signals as an example in which an inner-ring raceway of a bearing supporting a motor output shaft is damaged and, with time elapse, worsens stepwise in damage. More specifically, there are stored time [s] in column A, motor current [A] in column B, x-direction displacement [m] in column C, x-direction acceleration [m/s\hat{ }2] in column D, y-direction displacement [m] in column E, y-direction acceleration [m/s\hat{ }2] in column F, and output-shaft rotational speed [rpm] in column G. It is noted that a variable name is stored at the first row in every column. Also, it is set in FIG. 7, as an example, that first 4000-item data are of normal state and subsequent data worsen in damage more and more on an every 4000-item data basis. Hereinafter, description will be given on a basis that such a file is loaded.

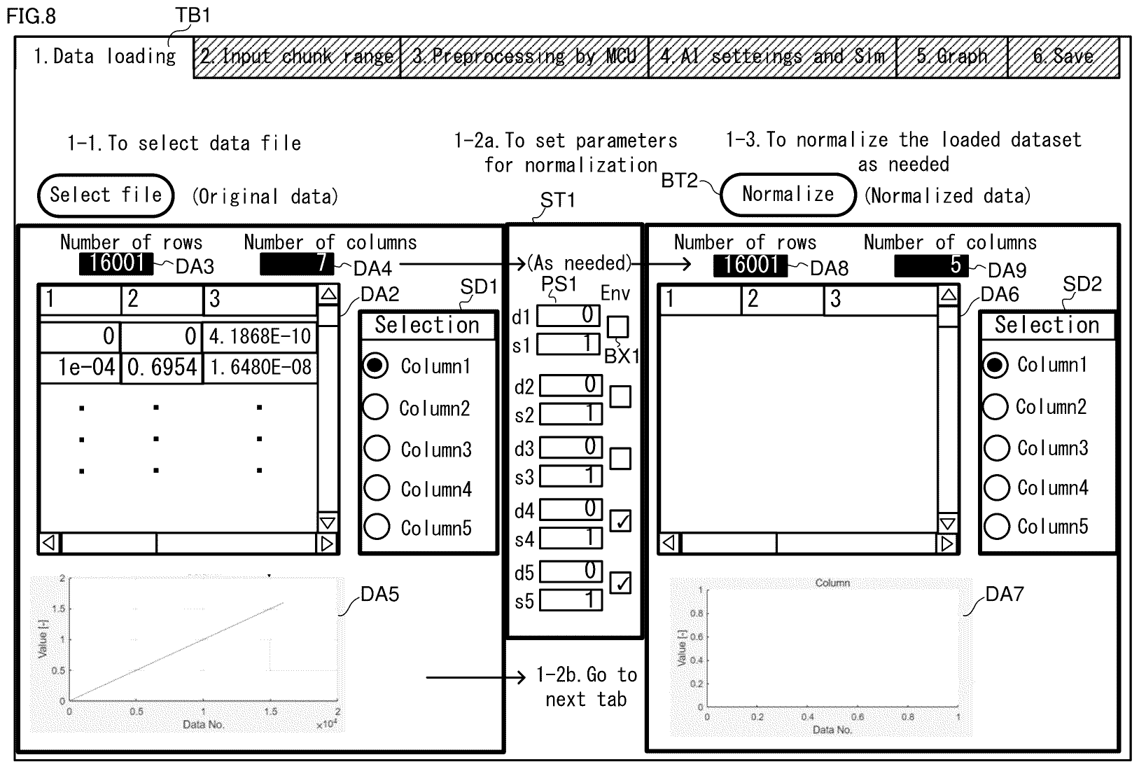

When a data file is loaded, data included in the loaded data file are displayed in a table form in a table display area DA2 in the first setting screen as shown in FIG. 8. In addition, data are loaded with the first row of the data file disregard. As a result, the user is allowed to verify that data have been loaded properly. Also, a row number of loaded data is displayed in a row-number display area DA3, while a column number of the loaded data is displayed in a column-number display area DA4. In the table display area DA2, all loaded data are displayed.

Meanwhile, as the data file is loaded, loaded data are graph-displayed on a column basis in a graph display area DA5 of the first setting screen as shown in FIG. 8. In the graph display, the horizontal axis represents data number, and the vertical axis represents data value. In a column selection portion SD1, any one of the first to fifth columns is selectable by radio buttons. Although data of the first column is graph-displayed by default, yet pressing the radio buttons allows a column for graph display to be changed over. In addition, whereas the sixth and following columns cannot be graph-displayed, data not has failed to be loaded, but has been loaded.

A preprocessing setting portion ST1 is displayed at a left-right center of the first setting screen (FIG. 8). In the preprocessing setting portion ST1, settings related to the normalization process and the envelope can be executed. For each of the first to fifth columns of the loaded data, the normalization process and the envelope process can be set individually.

The normalization process is executed by Expression (6) below:

$$\frac{{x}_{column i} - di}{{s}_{i}} \qquad ( 6 )$$

Where, X_{column i} is data of the ith column, and di and si are parameters for data of the ith column.

In a parameter setting portion PSI of the preprocessing setting portion ST1, parameters (di,si) for each of the first to fifth columns are settable. Depending on setting of the parameters, it is also possible to set the shift process or no process to be done.

Also, check boxes BX1 in the preprocessing setting portion ST1 are individually provided for the first to fifth columns, respectively. The envelope process is executed for a column checked at its check box BX1. The envelope process is not executed for a column unchecked at its check box BX1.

Pressing a preprocessing button BT2 in the first setting screen causes preprocessing to be executed for data of the first to fifth columns according to setting in the preprocessing setting portion ST1. In a table display area DA6 in the first setting screen, preprocessed data are displayed in a table form. In this case, data of the first to fifth columns are displayed. In a graph display area DA7, preprocessed data of a column selected by radio buttons of a selection portion SD2 is displayed. Its display form is similar to that of the graph display area DA5. In addition, displayed in a row display area DA8 and a column display area DA9 are a number of rows and a number of columns, respectively, of data that are displayed in the table display area DA6. Displayed in the column display area DA9 is a number of columns=5.

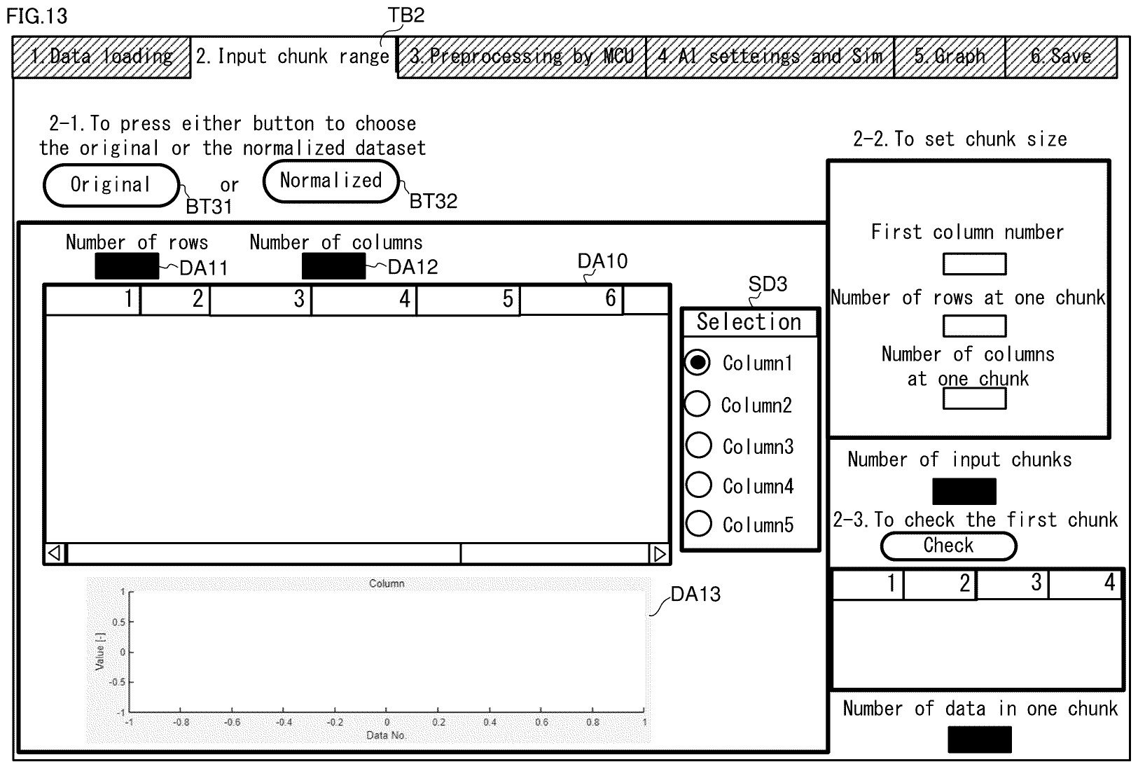

In addition, when the preprocessing is unnecessary, the screen is changed over by pressing a tab TB2 (FIG. 13 described later) without pressing the preprocessing button BT2.

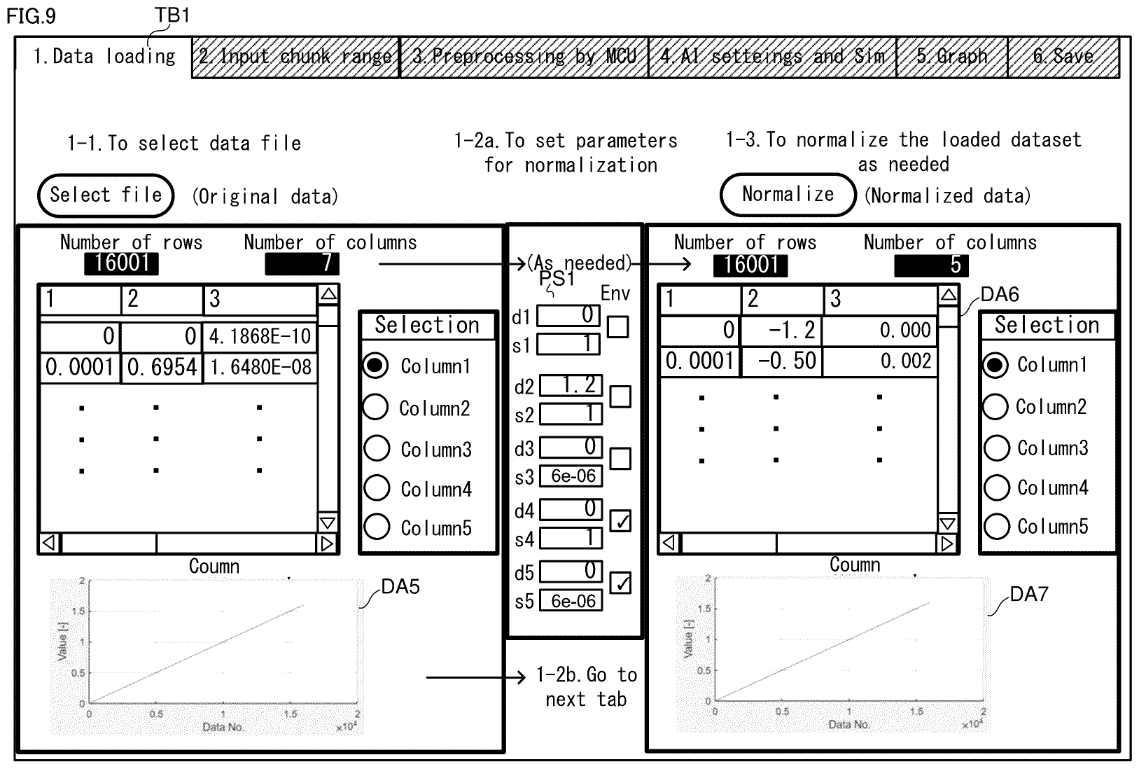

FIG. 9 is a view showing one example of preprocessing settings and processing results for Column 1. As shown in FIG. 9, d1 and s1, which are parameters of Column 1, are set to d1=0 and s1=1, respectively. In this case, it results that no process is executed. In addition, such a parameter setting is by default. In FIG. 9, display of the graph display areas DA5, DA7 is selected as the display of Column 1. Comparing the graph display areas DA5, DA7 to each other makes it known that data is free from any changes, with no processing done.

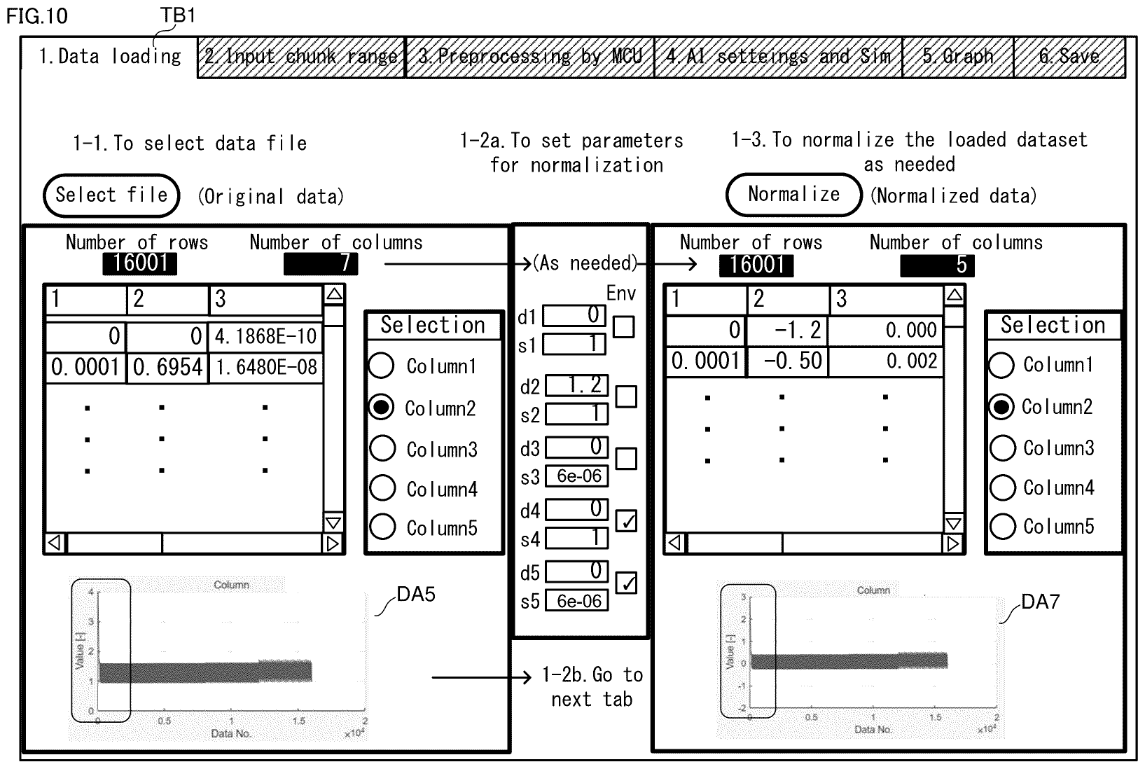

FIG. 10 is a view showing one example of preprocessing settings and processing results for Column 2. As shown in FIGS. 10, d2 and s2, which are parameters of Column 2, are set to d2=1.2 and s2=1, respectively. In FIG. 10, display of Column 2 is selected as display of the graph display areas DA5, DA7, respectively. Comparing the graph display areas DA5, DA7 to each other makes it understood that data has been shifted in a negative direction of the vertical axis after the preprocessing.

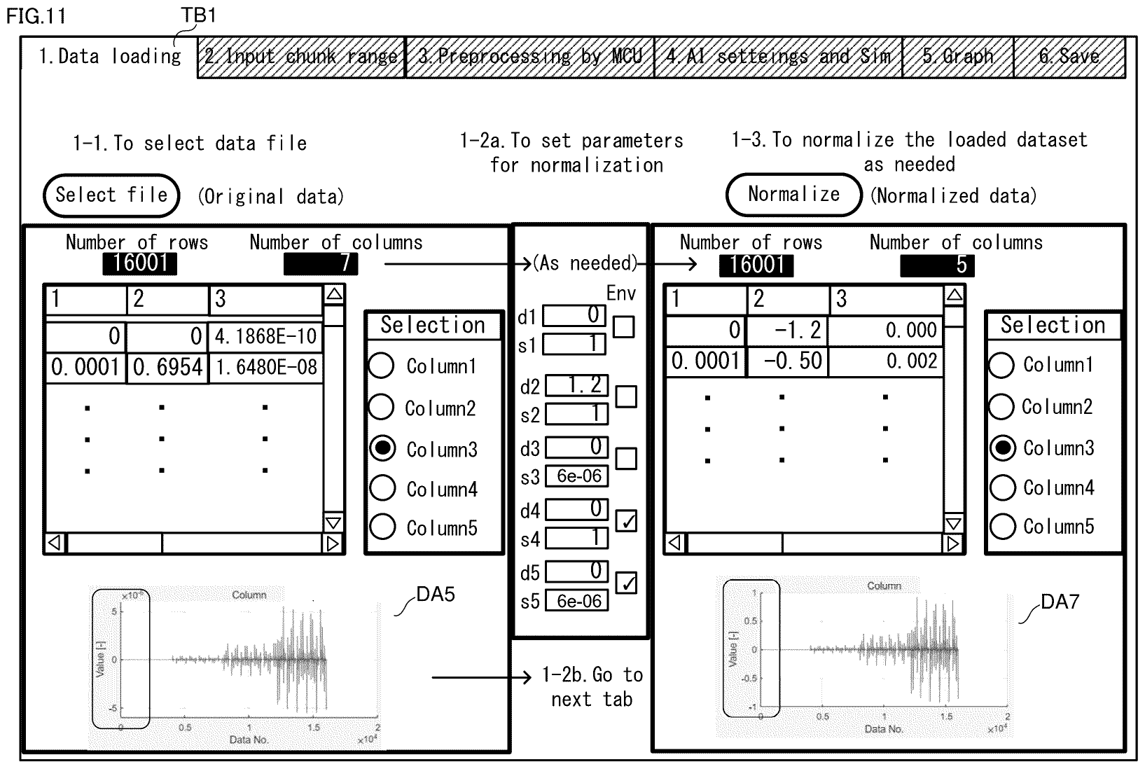

FIG. 11 is a view showing one example of preprocessing settings and processing results for Column 3. As shown in FIGS. 11, d3 and s3, which are parameters of Column 3, are set to d3=0, s3=6e-06, respectively. In FIG. 11, display of Column 3 is selected as display of the graph display areas DA5, DA7, respectively. Comparing the graph display areas DA5, DA7 to each other makes it understood that data has been enlarged in the vertical axis after the preprocessing while scaling has been changed.

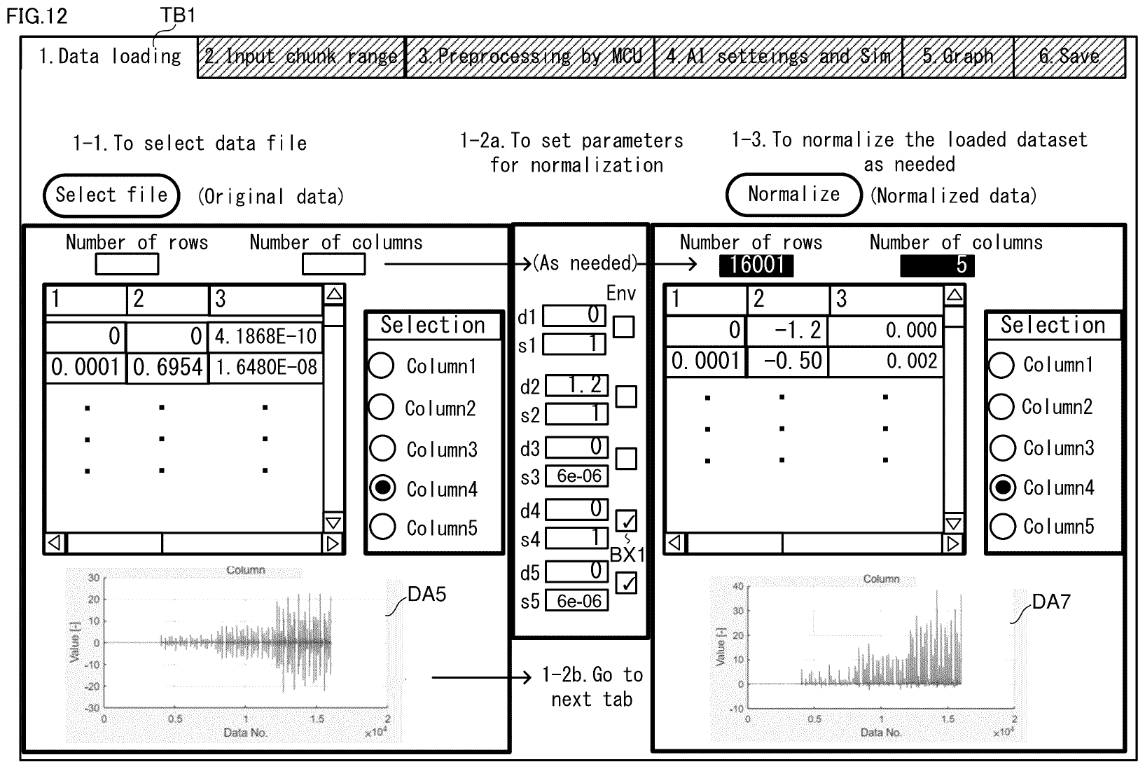

FIG. 12 is a view showing one example of preprocessing settings and processing results for Column 4. As shown in FIGS. 12, d4 and s4, which are parameters of Column 4, are set to d4=0 and s4=1, respectively. That is, the settings are as they are at default. However, execution of the envelope process for Column 4 has been selected (checked at the check box BX1). In FIG. 12, display of Column 4 has been selected as display of the graph display areas DA5, DA7, respectively. Comparing the graph display areas DA5, DA7 to each other makes it understood that an upper-side envelope has been extracted after the preprocessing.

### <<Second Setting Screen>>

When a tab 2 (“2. Input chunk range”) is pressed, a second setting screen as shown in FIG. 13 is displayed. In the second setting screen, data setting buttons BT31, BT32 are displayed, where either one of the buttons is to be pressed.

When the data setting button BT31 is pressed, data loaded in the first setting screen (original data) are used, as they are, as data which are to be entered into the machine learning model 40. When the data setting button BT32 is pressed, data acquired by executing preprocessing, which has been set in the first setting screen, on the data loaded in the first setting screen are used as the data to be entered into the machine learning model 40.

The data selected for use by either one of the data setting buttons BT31, BT32 are displayed in a table display area DA10 and a graph display area DA13. Data in the table display area DA10 are displayed in a table form. Display of the graph display area DA13 is changeable among the first to fifth columns by selecting a column with the radio buttons in a column selection portion SD3.

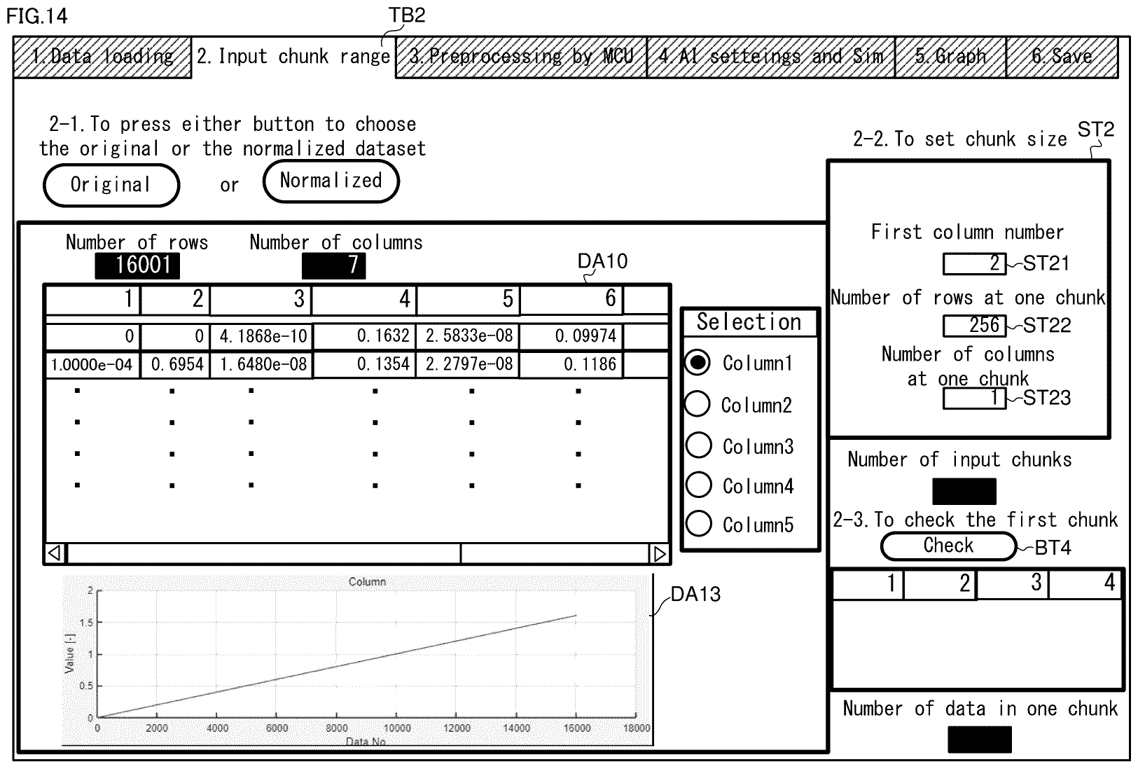

FIG. 14 is a view showing a state of the second setting screen in which the data setting button BT31 has been pressed (i.e., with original data in use). In the second setting screen, a chunk setting portion ST2 is displayed. The term, chunk, refers to a batch block of data in sequential entry into the machine learning model 40 (machine learning unit 402).

The chunk setting portion ST2 includes a column-number setting portion ST21, a number-of-rows setting portion ST22, and a number-of-columns setting portion ST23. A column number of in-use data (data selected by the data setting buttons BT31, BT32) indicating a first column of input data, which is to be entered into the machine learning model, can be entered into the column-number setting portion ST21. A number of rows of one chunk in the in-use data can be entered into the number-of-rows setting portion ST22. A number of columns of one chunk in the in-use data can be entered into the number-of-columns setting portion ST23.

In the example of FIG. 14, ‘2’ has been entered in the column-number setting portion ST21, ‘256’ has been entered in the number-of-rows setting portion ST22, and ‘1’ has been entered in the number-of-columns setting portion ST23. As a result, the second column of the in-use data is set as the first column of input data, and a block of data having 256 rows by 1 column is set as one chunk. That is, data of Column 2 (motor current in FIG. 7) has been selected as input data.

In addition, by setting a value of 2 or more in the number-of-columns setting portion ST23, data of plural columns, i.e. plural types of signal data or the like, may also be assigned as input data. For example, data of the motor current and the x-direction displacement in FIG. 7 may be assigned as input data.

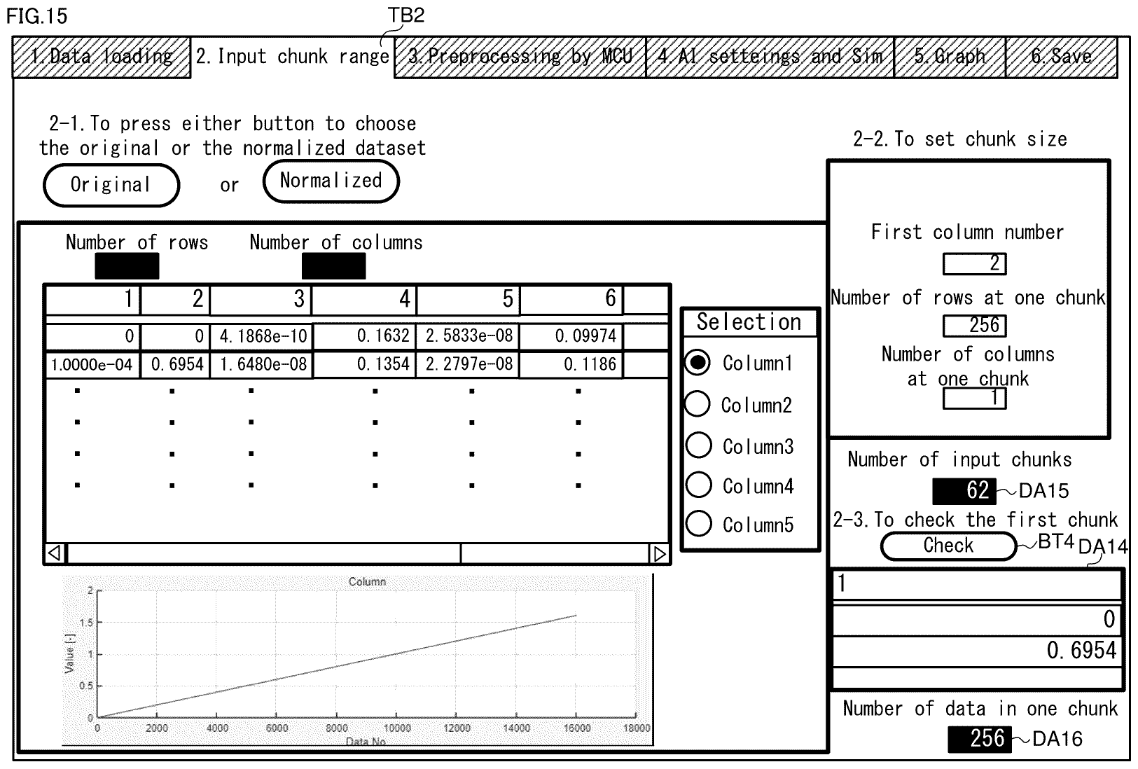

When a check button BT4 is pressed in the second setting screen, the screen goes as shown in FIG. 15, where a first chunk is displayed in a table form in the table display area DA14. As a result, it can be checked whether or not the chunk has been properly set. Also, a number of chunks calculated from a number of rows of the in-use data and a number of rows of one chunk is displayed in a number-of-chunks display area DA15 (number of chunks=62 in the example of FIG. 15). A number of data pieces included in one chunk is displayed in a number-of-data display area DA16. This number of data is equal to a product value resulting from multiplying a number of rows and a number of columns of one chunk (number of data=256 in the example of FIG. 15).

### <<Third Setting Screen>>

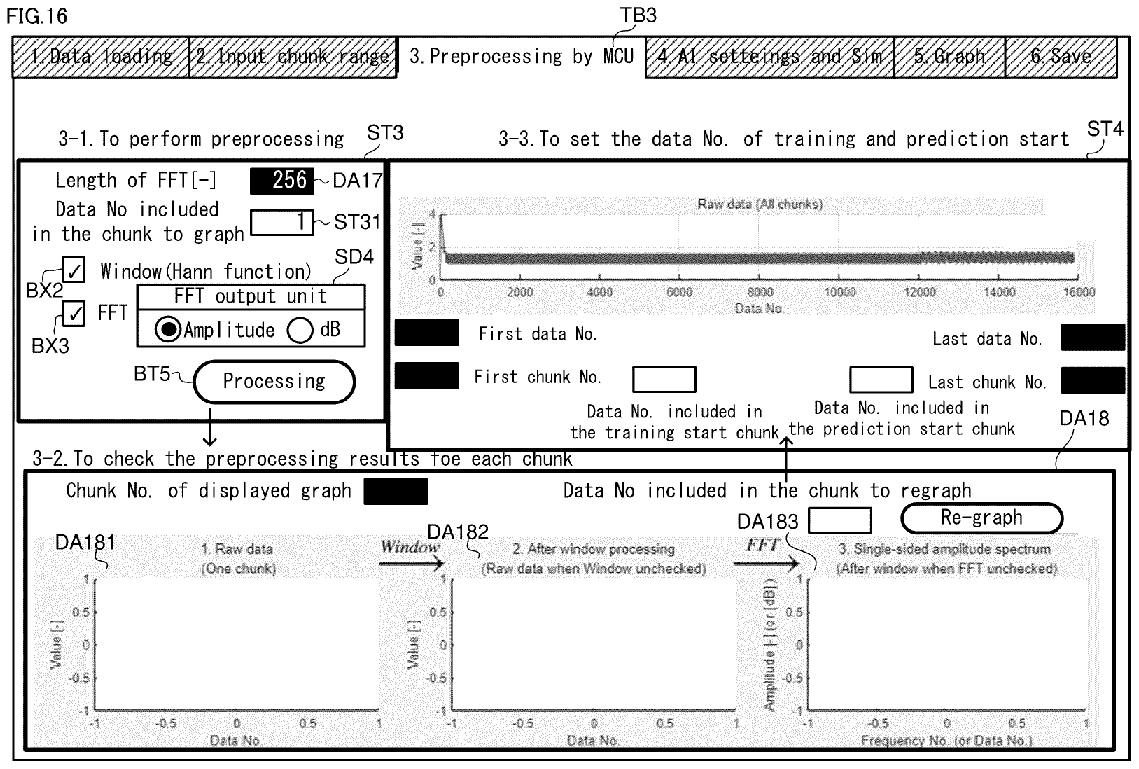

When a tab TB3 (“3. Preprocessing by MCU”) is pressed, a third setting screen as shown in FIG. 16 is displayed. In the third setting screen, applications of the preprocessing such as FFT executable by MCU (microcomputer) or the like are discussed.

A preprocessing setting portion ST3 is displayed in the third setting screen. In the preprocessing setting portion ST3, application or non-application is set for each of window function process and FFT process. Adoptable as the window function process are Hann window, Hamming window, Gauss window, triangular window, Kaiser window, Chebyshev window, Blackman window, and the like. More specifically, application or non-application of window function process is set by a check box BX2. Application or non-application of FFT process is set by a check box BX3. Further, in a display-unit selection portion SD4, a display unit (Amplitude or dB) of FFT process results can be selected by radio buttons.

In addition, the window function process and the FFT process are executed on a chunk-by-chunk basis. The FFT process or the like is based on algorithm suitable for calculations by the MCU. Data subjected to the FFT process is utilized only in terms of amplitude, resulting in a quantity of (FFT length)/2+1 relative to the FFT length (number of data included in one chunk). As to the FFT process, it may be made selectable from among cases where only amplitude is utilized, only phase is utilized, both amplitude and phase are utilized, and the like.

Also in the preprocessing setting portion ST3, an FFT length is displayed in an FFT length display area DA17.

When a preprocessing button BT5 is pressed, preprocessing set in the preprocessing setting portion ST3 is executed, with processing results displayed in a result display area DA18. The processing results are displayed on a chunk basis. A number of data included in a displayed chunk is settable in a data-number setting portion ST31 of the preprocessing setting portion ST3. As to data numbers, when a number of columns of a chunk is a plural number, serial numbers are assigned, as the data numbers, to data pieces, sequentially by starting with 1, of the same row and different columns in ascending order from the smallest row, the data numbers being serial numbers throughout all the chunks. For example, in a case with a column number of a chunk being three columns, numbers are assigned in an order from first column, second column and third column of the first row, to first column, second column and third column of the second row, . . . . Referring to FIG. 15 described above, since a chunk setting is 256 rows by 1 column, data numbers of 1 to 256 belong to the same first chunk.

In the result display area DA18, displayed from left to right are a raw-data display area DA181, an after-window-function-process display area DA182, and an after-FFT-process display area DA183. Data (unprocessed data) of one chunk are displayed in the raw-data display area DA181. Data subjected to the window function process of one-chunk data are displayed in the after-window-function-process display area DA182. Data derived from FFT process of data subjected to the window function process are displayed in the after-FFT-process display area DA183. In addition, in every case of the raw-data display area DA181, the after-window-function-process display area DA182, and the after-FFT-process display area DA183, graph display is given on the assumption that the horizontal axis represents data number (i.e., serial number with the first data item in a target chunk assumed as 1) while the vertical axis represents data value.

However, when the window function process is not applied and only the FFT process is executed as an example, raw data are displayed in the after-window-function-process display area DA182. When neither the window function process nor the FFT process is applied, raw data are displayed in all of the raw-data display area DA181, the after-window-function-process display area DA182, and the after-FFT-process display area DA183. In any case, data displayed in the after-FFT-process display area DA183 become input data to be entered into the machine learning unit 402 (three-layer neural network 10).

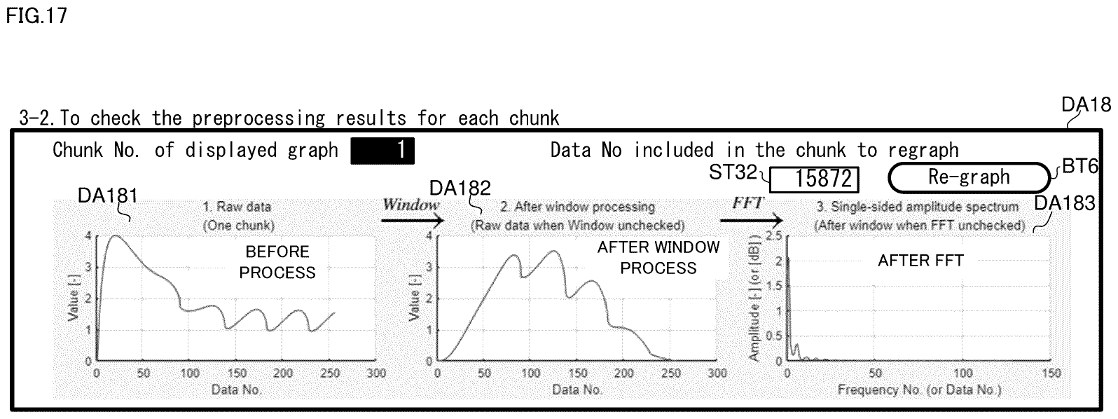

FIG. 17 is a display example of processing results when both the window function process and the FFT process are applied. After the FFT process, a number of data has decreased. In addition, in the result display area DA18, a data-number setting portion ST32 is displayed. In the data-number setting portion ST32, a data number corresponding to a chunk to be redisplayed in the result display area DA18 is settable. When a redisplay button BT6 is pressed, the processing results are redisplayed in the result display area DA18.

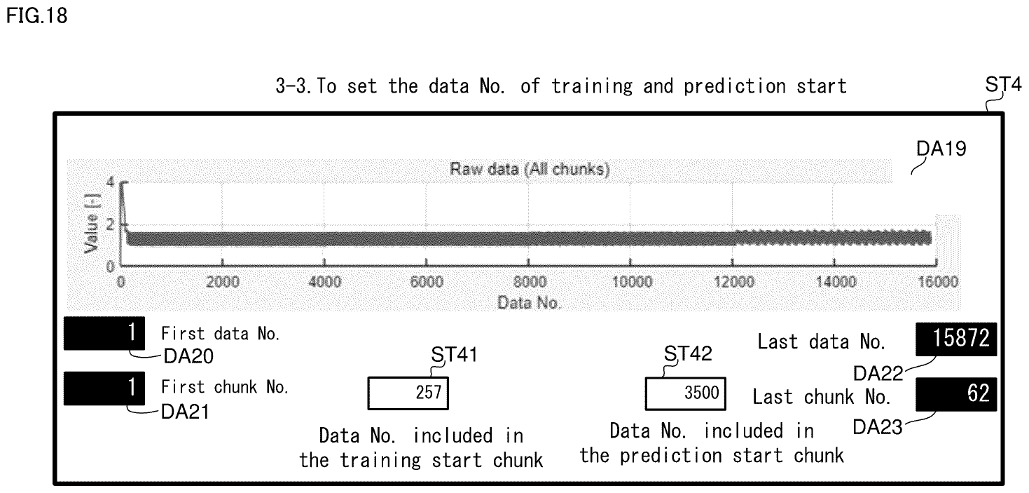

Next, a training-and-prediction setting portion ST4 (FIG. 16) in the third setting screen is described. FIG. 18 shows the training-and-prediction setting portion ST4. In the training-and-prediction setting portion ST4, a raw-data display area DA19 is displayed. In the raw-data display area DA19, data (unprocessed data) of all the chunks set in the second setting screen are graph-displayed. The display is given on the assumption that the horizontal axis represents data number while the vertical axis represents data value.

Under the raw-data display area DA19, displayed at a left end portion are a first-data-number display area DA20 and a first-chunk-number display area DA21. A first data number (‘l’ in FIG. 18) is displayed in the first-data-number display area DA20, and a first chunk number (‘1’ in FIG. 18) is displayed in the first-chunk-number display area DA21.

Under the raw-data display area DA19, displayed at a right end portion are a last-data-number display area DA22 and a last-chunk-number display area DA23. A last data number is displayed in the last-data-number display area DA22, and a last number of chunk numbers is displayed in the last-chunk-number display area DA23. In the example of FIG. 18, since a chunk setting is 256 rows by 1 column as in the example of FIG. 15 and a number of data of one column is 16001 as shown in FIG. 7, it follows that chunk number=62 (last chunk number), with the last data number equal to 62×256=15872.

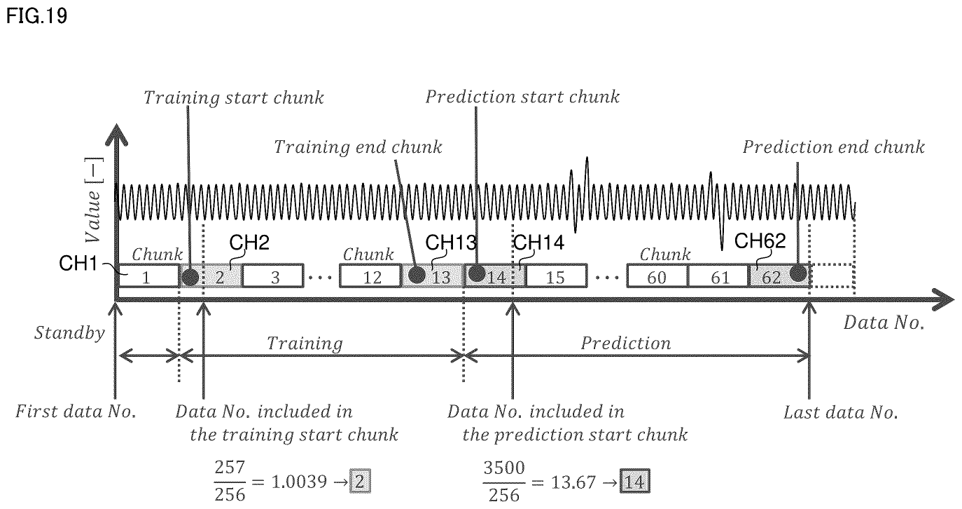

Training and prediction with the machine learning unit 402 are performed in a chunk unit. First, one of data numbers included in a chunk, which is a desired object of training start, is entered and set into a data-number setting portion ST41. FIG. 19 is a view treating settings of training and prediction as to array of raw data, as in FIG. 18. In the case of motor currents that are data of Column 2 in the example of FIG. 7, a current increase can be recognized upon motor start-up. When training of this current increase is undesired, it is effective to start training with the second chunk CH2 (chunk number=2). Accordingly, for example, setting a value of 257, which is a data number included in the second chunk CH2, causes training to be started with the second chunk CH2 while the first chunk CH1 is not used for training.

Subsequently, one data number included in a chunk, which is a desired object of prediction start, is entered and set into a data-number setting portion ST42 (FIG. 18). In the example of FIG. 7, the motor current makes transition to an anomaly state at a data number of 4000 and on. Because of normal state so far, here is set a data number of 3500 as an example, and only the normal state is used for training. In addition, the data number of 3500 corresponds to a chunk CH14 of chunk number=14, as shown in FIG. 19. Thus, in the example of FIG. 19, the chunk CH1 is not used for training, the chunks CH2 to CH13 are used for training, and the chunks CH14 to last chunk CH62 are used for prediction.

### <<Fourth Setting Screen>>

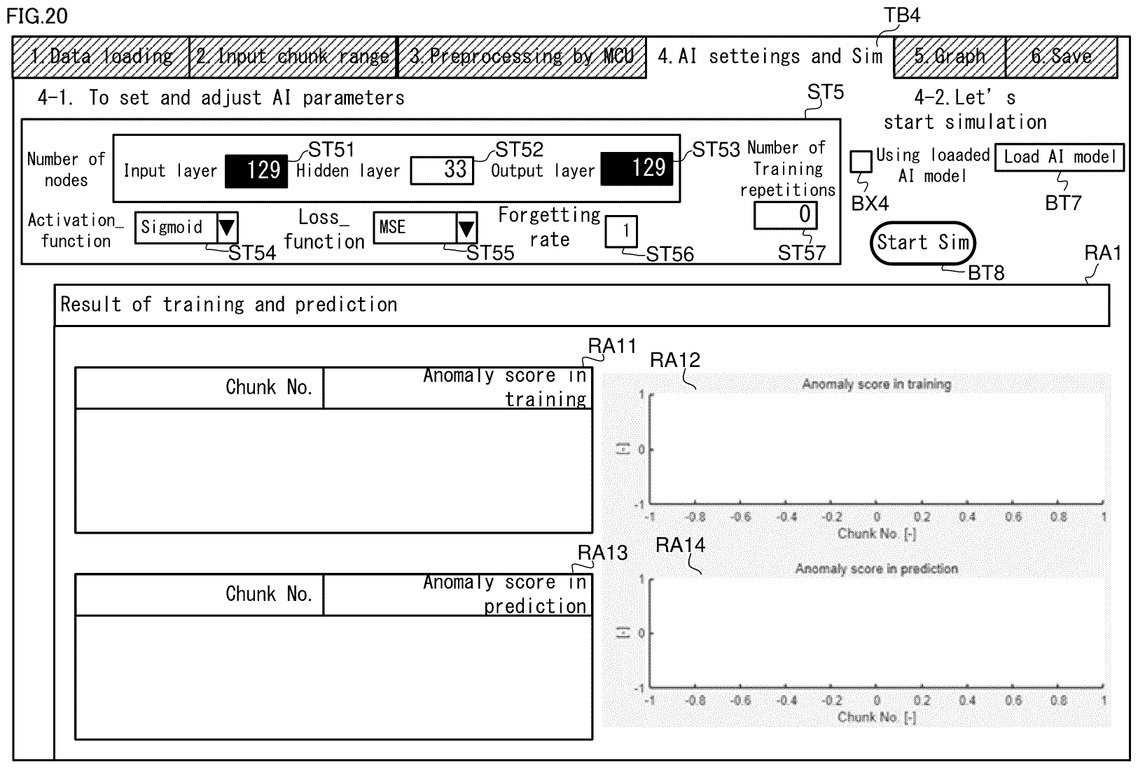

When a tab TB4 (“4. AI Settings and Sim”) is pressed, a fourth setting screen as shown in FIG. 20 is displayed. The fourth setting screen is a screen intended for parameter setting of the machine learning unit 402, execution of simulations, and result confirmation of simulations.

In the fourth setting screen shown in FIG. 20, an AI parameter setting portion ST5 is displayed. Included in the AI parameter setting portion ST5 are an input-node-number setting portion ST51, a hidden-layer node number setting portion ST52, and an output-node-number setting portion ST53. In the input-node-number setting portion ST51, a node number (value of n mentioned above) of the input layer 10A is displayed. The node number of the input layer is calculated by multiplying a number of rows and a number of columns of one chunk in the input data. That is, one-chunk data corresponds to data having a batch size of 1. In addition, in the example of FIG. 20, in order to allow data after FFT process to be entered into the machine learning unit 402 as shown in FIG. 17, the data number of one chunk is decreased from 256 to 129, and the number of 129 is set as an input node number.

The hidden-layer node number setting portion ST52 allows the node number (value of m mentioned above) of the hidden layer 10B to be entered thereinto. In the output-node-number setting portion ST53, a node number (value of n′ mentioned above) of the output layer 10C is displayed. Because of the autoencoder, the output node number is equal to the input node number.

Also included in the AI parameter setting portion ST5 are an activation-function setting portion ST54, a loss-function setting portion ST55, and a forgetting-rate setting portion ST56. In the activation-function setting portion ST54, a type of the activation function in the hidden layer 10B is selectable. For the activation function, Sigmoid, ReLU or the like is settable, as an example.

In the loss-function setting portion ST55, settable is a type of the loss function to be used for calculation of the anomaly score in the machine learning unit 402. For the loss function, MAE or MSE may be set, as an example.

In the forgetting-rate setting portion ST56, a value of the forgetting rate is enterable. The forgetting rate is a parameter representing a degree of forgettability for training results. Methods in which no training results are reflected may include, for example, using training results of the past, initializing training results, and the like. A forgetting rate of 1 represents no forgetting of past training results, while a forgetting rate of 0 represents forgetting all of training results.

Also, in the AI parameter setting portion ST5, a training-repetition-number setting portion ST57 is also displayed. Settable in the training-repetition-number setting portion ST57 is a number of times to which training is repeated.

In the fourth setting screen shown in FIG. 20, also displayed are a loading button BT7 for loading of the machine learning model 40 that has been saved (non-temporarily stored in the auxiliary storage device 100C), as well as a check box BX4. Saving of the machine learning model 40 will be described later.

When the loading button BT7 is pressed, a dialog box for designation of a machine learning model 40 to be loaded is displayed. When designation of the machine learning model 40 to be loaded is completed in the dialog box, the designated machine learning model 40 is loaded, followed by reflection of the loaded contents in the AI parameter setting portion ST5 as well as by automatic checking in the check box BX4.

By the loading button BT7 being pressed, it becomes practicable to use a machine learning model 40 (trained machine learning model 40) that has been non-temporarily stored in the model storage unit 4 and subjected to computations of training. In addition, when the machine learning model 40 (trained machine learning model 40) after having been subjected to computations of training is used, it is appropriate to allow the user to make selection between, for example, a process of executing both computations of training and computations of prediction and a process of executing only computations of prediction without executing computations of training.

After settings of all the setting items have been completed by the above-described setting screens, and as a simulation start button BT8 is pressed, the model computing unit 5 executes a simulation according to contents set by the model setting unit 6. In this case, data are entered to the machine learning unit 402 sequentially on a chunk-unit basis, followed by sequential updating of β by the above-described algorithm and execution of unsupervised training. In terms of data input, data are entered to individual nodes of the input layer 10A in a data-number sequence of chunks. During training process, prediction by the machine learning unit 402 is also executed. Further, after completion of training, prediction by the machine learning unit 402 is executed as well. Prediction results are calculated on a chunk-by-chunk basis. Also, anomaly scores are calculated based on prediction results, input data, and the loss function on a chunk-by-chunk basis.

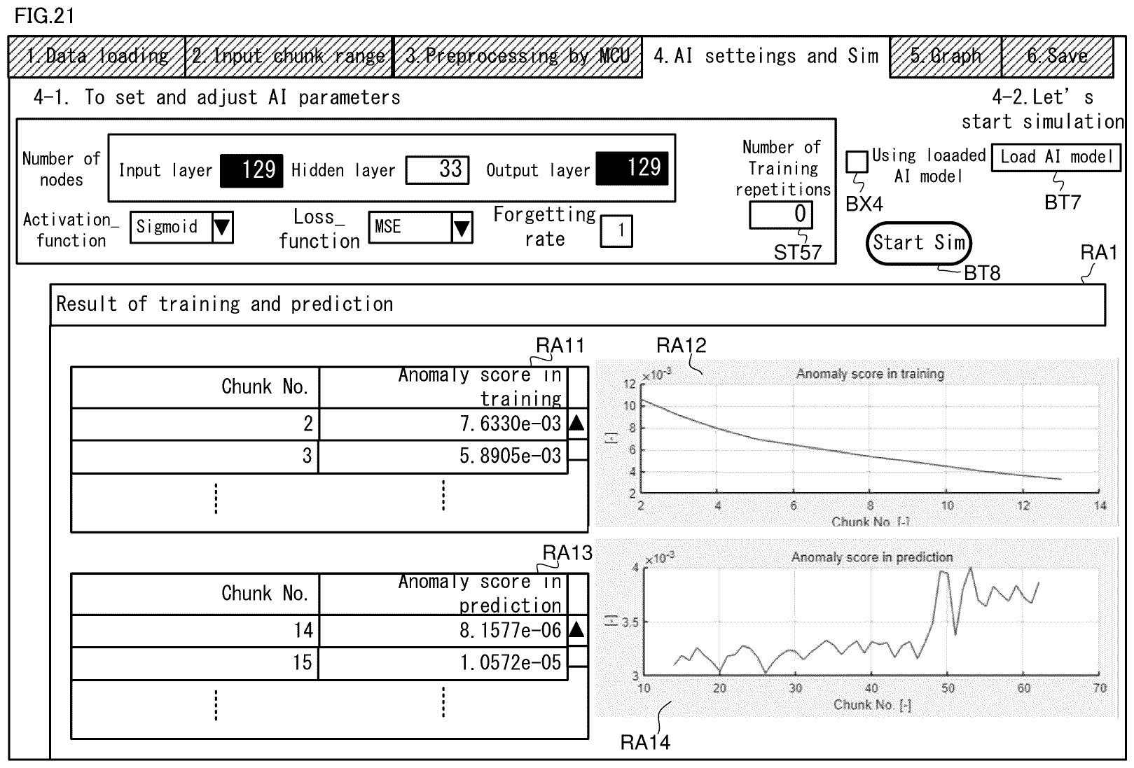

Simulation results are displayed in a result display area RA1 of the fourth setting screen, for example, as shown in FIG. 21. An anomaly-score table display area RA11, and an anomaly-score graph display area RA12 are displayed in an upper stage of the result display area RA1. In the anomaly-score table display area RA11, anomaly scores of individual chunks in training are displayed in a table form. In the anomaly-score graph display area RA12, anomaly scores of individual chunks in training are displayed in a graph form. In both the anomaly-score table display area RA11 and the anomaly-score graph display area RA12, chunk numbers and anomaly scores are displayed in correspondence.

An anomaly-score table display area RA13, and an anomaly-score graph display area RA14 are displayed in a lower stage of the result display area RA1. In the anomaly-score table display area RA13, anomaly scores of individual chunks in prediction after completion of training are displayed in a table form. In the anomaly-score graph display area RA14, anomaly scores of individual chunks in prediction after completion of training are displayed in a graph form. In both the anomaly-score table display area RA13 and the anomaly-score graph display area RA14, chunk numbers and anomaly scores are displayed in correspondence.

In this case, when the simulation start button BT8 is pressed with data having been entered in the training-repetition-number setting portion ST57, training with use of all the training-intended chunks (in the example of FIG. 19, chunks CH2 to CH13) is reused up to a number of times set to the training-repetition-number setting portion ST57. That is, when the chunks are used up to the last chunk, training is resumed by reverting to the first chunk.

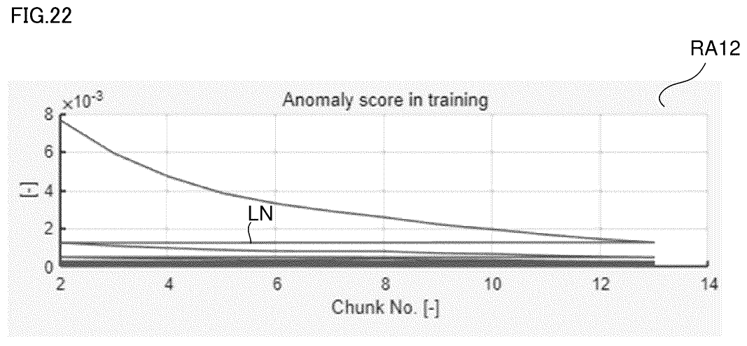

In the example of FIG. 21, since the number of times set in the training-repetition-number setting portion ST57 is 0, no repetition of training is executed, and the anomaly score decreases gradually as displayed in the anomaly-score graph display area RA12 of FIG. 21, with the training ended on a decrease process. Ideally, it is desirable that the anomaly score be on a plateau showing that sufficient training has been accomplished. However, there are some cases where it is hard to prepare long-term data for implementation of such training as described above. Therefore, setting the number of times for the training-repetition-number setting portion ST57 to 1 or more makes it possible to easily accomplish training such that the anomaly score keeps on a plateau. FIG. 22 shows a display example of the anomaly-score graph display area RA12 under a condition that the number of times for setting in the training-repetition-number setting portion ST57 is set to 20. In this case, 20 times of turnover line LN is displayed, and training is repeated like this, finally resulting in the anomaly score approaching a plateau state (number of training times of 20+1=21).

### <<Graph Screen>>

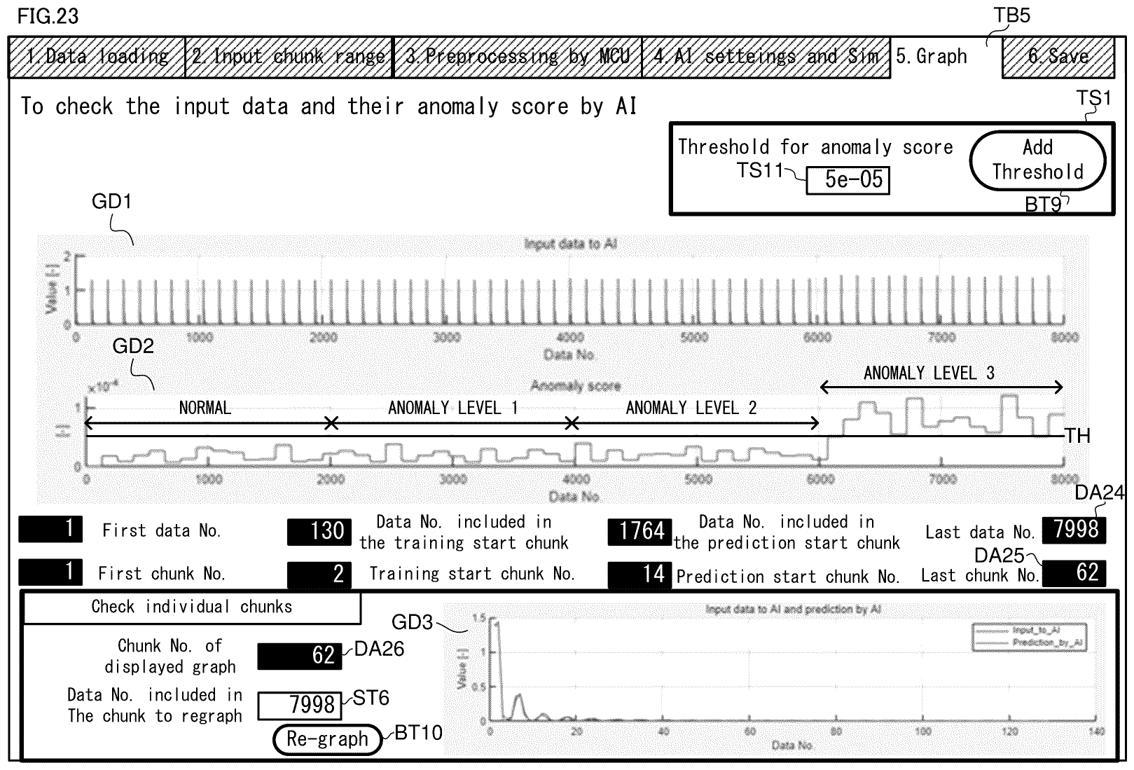

When a tab TB5 (“5. Graph”) is pressed, a graph screen as shown in FIG. 23 is displayed. In the graph screen, a graph display area GD1 is displayed in an upper stage while a graph display area GD2 is displayed in a lower stage. In the graph display area GD1, displayed are values of input data versus all data (data composed of all chunks) entered into the machine learning unit 402, where the horizontal axis represents data number. In addition, in the example of FIG. 23, since data obtained by executing the window function process and the FFT process on a chunk-by-chunk basis in the third setting screen is assumed as input data, a range from splinter-like peak to immediately before next peak corresponds to one chunk. Also, because of the FFT process, the last data number, although being 15872 (FIG. 18) in the third setting screen, has come to 7998, which is about one half (last-data-number display area DA24). In addition, the last chunk number is 62 as in the third setting screen (last-chunk-number display area DA25).

In the graph display area GD2, values of anomaly score versus all data entered into the machine learning unit 402 are displayed. The horizontal axis represents data number. As to the data of FIG. 7, it has proved that a first quarter of all the data were in normal state, and a second three quarters were in anomaly state. In the graph display area GD2, displayed are an anomaly score of normal state as well as anomaly scores of three-stage anomaly states.

Entering a threshold of anomaly score into a threshold input portion TS11 and pressing a setting button BT9 in a threshold setting portion TS1 located upper rightward in the graph screen causes a threshold TH set in the graph display area GD2 to be displayed. In the example of FIG. 23, the threshold value is set to 5e-05 so as to enable identification of anomaly level 3.

Further, a graph display area GD3 is displayed in the lowermost stage of the graph screen. In the graph display area GD3, data entered into the machine learning unit 402 and prediction results by the machine learning unit 402 are displayed in comparison with each other on a chunk-by-chunk basis. The horizontal axis, in the display, represents data number (serial number with the first data item in a target chunk assumed as 1). In addition, a chunk-number display area DA26 and a data-number setting portion ST6 are displayed leftward of the graph display area GD3. Displayed in the chunk-number display area DA26 is a chunk number of a chunk which is displayed in the graph display area GD3. At default, the last chunk number is displayed. In the data-number setting portion ST6, a data number included in a chunk which is redisplayed in the graph display area GD3 is settable. After the setting into the data-number setting portion ST6, pressing a redisplay button BT10 causes the graph display area GD3 to be redisplayed.

When the graph display area GD3 is displayed as to a chunk of large anomaly scores, there is involved an increased alienation between input data and prediction value.

### <<Save Screen>>

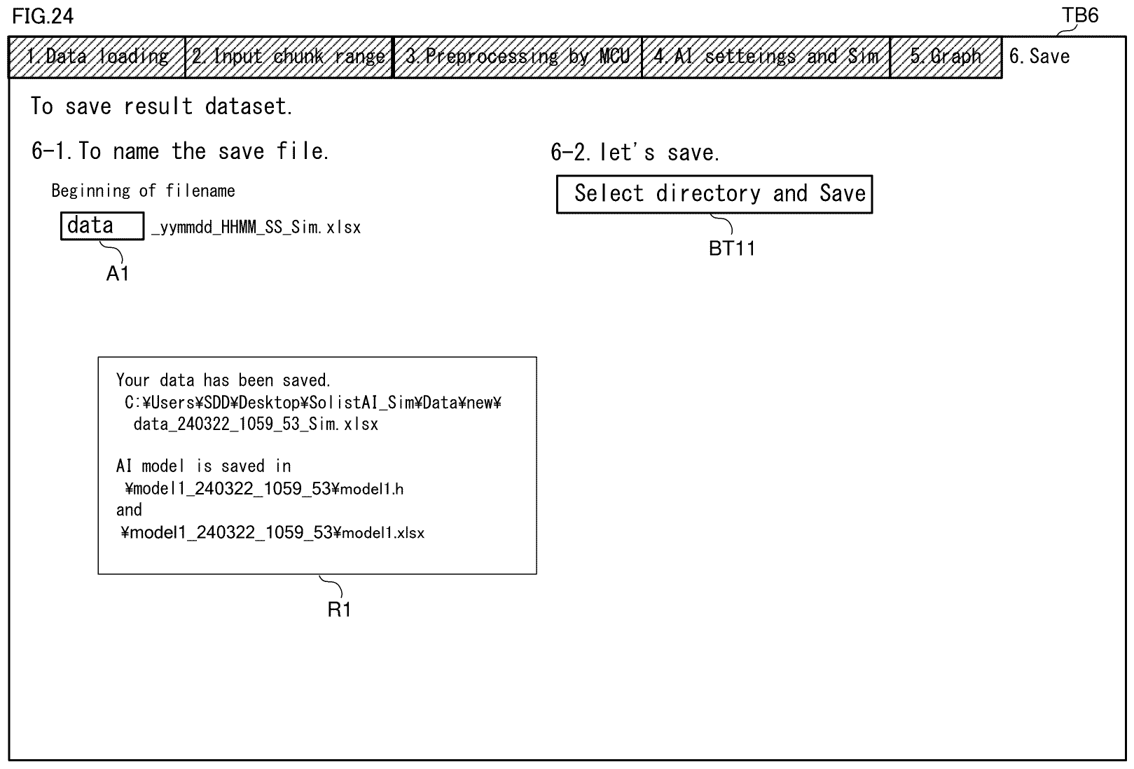

When a tab TB6 (“6. Save”) is pressed, a save screen as shown in FIG. 24 is displayed. In the save screen shown in FIG. 24, a character input area AI and a save button BT11 are displayed as well.

Editing text within the character input area AI allows a leading character string of a save file name to be changed. The save file shows training results and prediction results.

When the save button BT11 is pressed, a dialog box for selection of a save-destination folder is displayed. With a save-destination folder selected in the dialog box, saving gets started; upon completion of the saving, a save result R1 is displayed.

In the save process described above, in addition to a file showing training results and prediction results, the machine learning model 40 (trained machine learning model 40) after execution of computations of training is non-temporarily stored by the model storage unit 4. Accordingly, the model storage unit 4 non-temporarily stores not only the machine learning model 40 before execution of the computations of training but also the machine learning model 40 (trained machine learning model 40) after execution of the computations of training. As a consequence of this, it becomes implementable to give over, to other devices, the machine learning model 40 (trained machine learning model 40) after execution of the computations of training, and to perform sequential training and re-training with the machine learning model 40 (trained machine learning model 40) after execution of the computations of training, and the like.

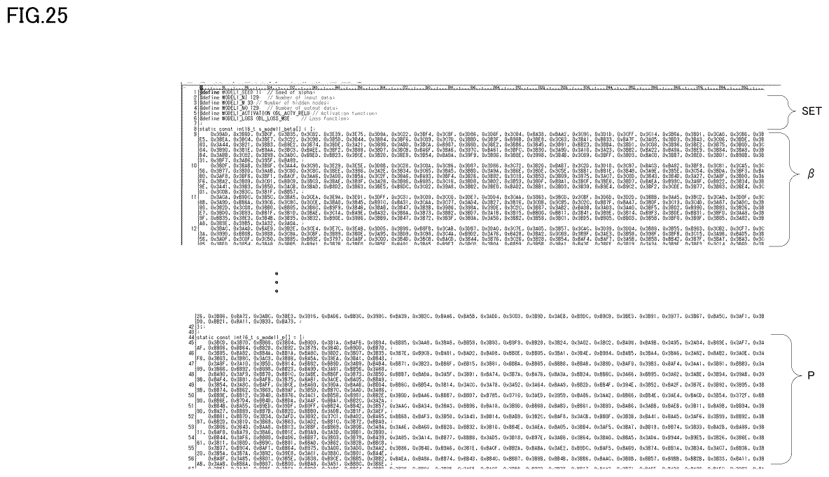

In the simulation apparatus 1, when an operation of, as an example, opening “a file model1_240322_1059_53¥model1.h” is performed, B and P that are internal parameters of the machine learning model 40 (trained machine learning model 40) after execution of the computations of training are displayed in a matrix form as shown in FIG. 25. In addition, the file identified by “model1_240322_1059_53¥model1.h” includes not only internal parameters of the machine learning model 40 (trained machine learning model 40) after execution of the computations of training but also setting contents SET of the machine learning model 40 (trained machine learning model 40) after execution of the computations of training. The setting contents SET include, for example, a node number of the input layer 10A, a node number of the hidden layer 10B, a node number of the output layer 10C, a type of the activation function of the hidden layer 10B, a type of the loss function, a random seed value of weight α, and the like.

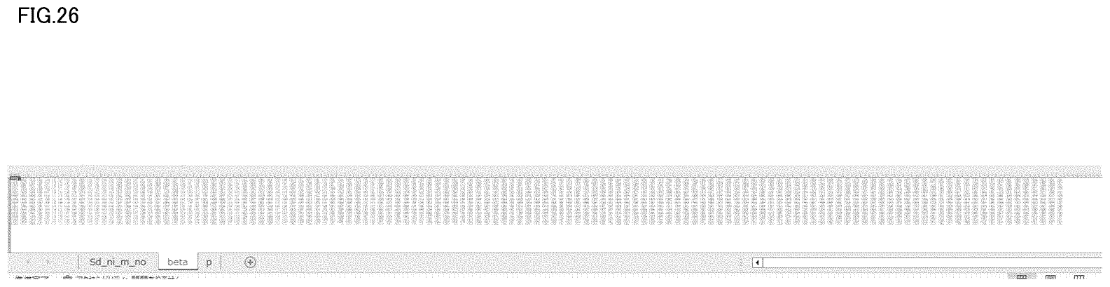

In the simulation apparatus 1, when an operation of, for example, opening “¥model1_240322_1059_53¥model1.xlsx” is performed and a sheet including data of β is selected, the data of β that is an internal parameter of the machine learning model 40 (trained machine learning model 40) after execution of the computations of training are displayed in a matrix form as shown in FIG. 26.

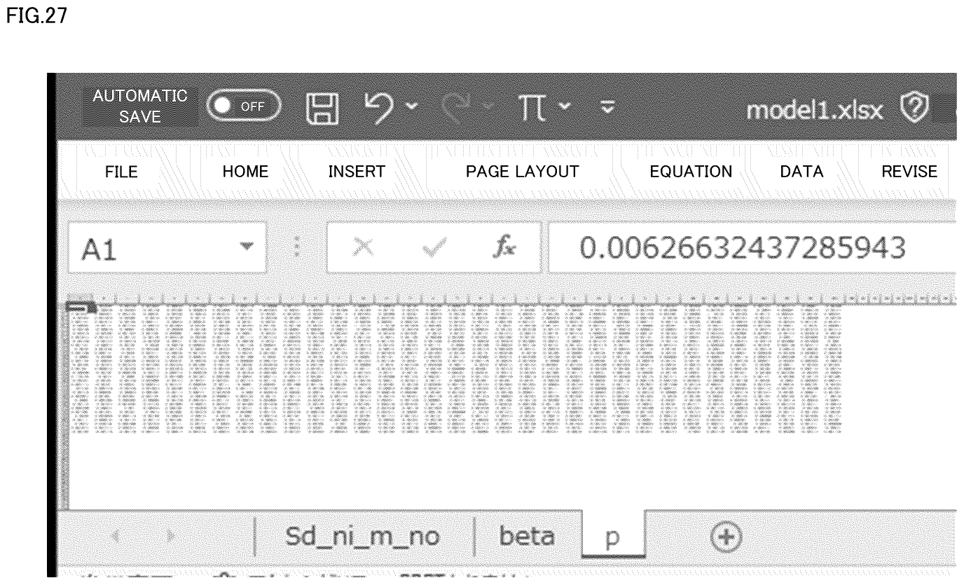

In the simulation apparatus 1, when an operation of, for example, opening “¥model1_240322_1059_53¥model1.xlsx” is performed and a sheet including data of P is selected, the data of P that is an internal parameter of the machine learning model 40 (trained machine learning model 40) after execution of the computations of training are displayed in a matrix form as shown in FIG. 27. The file identified by “¥model1_240322_1059_53¥model1.xlsx” includes not only internal parameters of the machine learning model 40 (trained machine learning model 40) after execution of the computations of training, but also a sheet including setting contents of the machine learning model 40 (trained machine learning model 40) after execution of the computations of training. The setting contents include, for example, a node number of the input layer 10A, a node number of the hidden layer 10B, a node number of the output layer 10C, a type of the activation function of the hidden layer 10B, a type of the loss function, a random seed value of weight α, a floating-point format, and the like.

### Others

In addition, various technical features disclosed herein may be carried out not only as in the above-described embodiment but also as changed or modified without departing from the gist of the technical creation of the disclosure. That is, the embodiment disclosed herein should be construed as not being limitative but being an exemplification at all points. The technical scope of the disclosure is defined not by the above description of the embodiment but by the appended claims, including all changes and modifications equivalent in sense and range to the claims.

For example, although chunks are set in a two-dimensional format with row number and column number in the above embodiment, yet it is also allowable to set the chunks in a three- or more-dimensional format.

Furthermore, for example, although the machine learning model 40 (trained machine learning model 40) after execution of the computations of training is non-temporarily stored in the above embodiment, yet a machine learning model after execution of part of the computations of training may be non-temporarily stored. For example, a machine learning model on halfway of training may be non-temporarily stored each time training with each chunk is ended, or a machine learning model on halfway of training may be non-temporarily stored each time training with a specified number (2 or more) of chunks is ended.

### Appendices

As described hereinabove, a simulation apparatus (1) according to one aspect of the present disclosure comprises:
a model storage unit (4) in which a machine learning model (40) configured to execute training and prediction has been stored;
a model computing unit (5) configured to execute computing process by using the machine learning model;
an operation input portion (8);
a loading unit (3) configured to load data; and
a model setting unit (6) configured to execute setting related to the machine learning model on a basis of input by the operation input portion,
wherein
the model setting unit is configured to, on a basis of the loaded data, execute setting related to a chunk as a batch block of data in a case where data are sequentially entered into the machine learning model,
the model computing unit is configured to execute computations of unsupervised training and computations of prediction by sequentially entering the chunk into the machine learning model, and
the model storage unit is configured to non-temporarily store not only the machine learning model before execution of the computations of training but also the machine learning model after execution of at least part of the computations of training (first configuration).

In the simulation apparatus of the first configuration, the model setting unit may be so configured that setting with time-series data of plural types of signals included in the chunk is possible (second configuration).

Also, in the simulation apparatus of the first or second configuration, the model setting unit may be so configured that setting a column number of a first column, a number of rows, and a number of columns on a basis of the loaded data allows setting of the chunk to be fulfilled (third configuration).

Also, in the simulation apparatus of any one of the first to third configurations, the machine learning model may further include a first preprocessing unit (401) configured to execute normalization process with the loaded data by Expression below, and the model setting unit may be so configured that parameters of the following expression are settable (fourth configuration):

$$\frac{{x}_{column i} - {d}_{i}}{{s}_{i}}$$

where xcolumn i is the data of the ith column, and di and si are parameters in conjunction with the data of the ith column.

Also, in the simulation apparatus of any one of the first to fourth configurations, the machine learning model may include a second preprocessing unit (401) configured to execute envelope process with the loaded data, and
the model setting unit may be so configured that execution or non-execution of the envelope process is settable on a column-by-column basis of the loaded data (fifth configuration).

Also, in the simulation apparatus of any one of the first to fifth configurations, the machine learning model may include a third preprocessing unit (401) configured to execute window function process and frequency analysis process on the chunk-by-chunk basis, and
the model setting unit may be so configured that execution or non-execution of the window function process and the frequency analysis process, respectively, is settable (sixth configuration).

Also, in the simulation apparatus of any one of the first to sixth configurations, the model setting unit may be configured to be able to set a training start chunk, which is the chunk for starting training by the machine learning model, as well as a prediction start chunk, which is the chunk for starting prediction by the machine learning model (seventh configuration).

Also, in the simulation apparatus of the seventh configuration, setting of the training start chunk and the prediction start chunk may be executed by setting of a number of data included in the chunk, and
the number of data may be defined as increasing numbers sequentially assigned to data, in a case where plural columns of each chunk are involved, the increasing numbers being assigned to data pieces of different columns in order from smaller to larger column numbers in each one row out of rows starting with the smallest row number and increasing in order from smaller to larger row numbers (eighth configuration).

Also, in the simulation apparatus of any one of the first to eighth configurations, the model setting unit may be so configured that items related to a neural network (10) included in the machine learning model are settable (ninth configuration).

Also, in the simulation apparatus of the ninth configuration, the items may include a forgetting rate which is a parameter representing a degree of forgettability as to training results (tenth configuration).

Also, in the simulation apparatus of any one of the first to tenth configurations, the model setting unit may be so configured that a number of times to which training using all the chunks is repeated is settable (eleventh configuration).

Also, in the simulation apparatus of the first configuration, the model setting unit may be so configured that a number of times to which training using all the chunks is repeated is settable, and
the simulation apparatus may further include a first display control portion which is so configured that values of the loss function relative to all the chunks, with a turnover-line line (LN) from the last chunk to the first chunk included, are displayed to the set number of repetition times (twelfth configuration).

Also, in the simulation apparatus of any one of the first to twelfth configurations, the simulation apparatus may further include a second display control portion (7) which is so configured as to execute control for displaying values of the loss function based on prediction results during and after training by the machine learning model, in correspondence to serial numbers of data included in all the chunks (thirteenth configuration).

Also, in the simulation apparatus of the thirteenth configuration, the model setting unit may be so configured that a threshold for values of the loss function displayed in display by the third display control portion is settable (fourteenth configuration).

Also, in the simulation apparatus of any one of the first to fourteenth configurations, the simulation apparatus may further include a third display control portion (7) which is so configured as to execute control for displaying prediction results by the values of data and the machine learning model in correspondence to serial numbers of data included in one of the chunks, and
the model setting unit may be configured to be able to set the chunk that is redisplayed in the third display control portion (fifteenth configuration).

Also, in the simulation apparatus of any one of the first to fifteenth configurations, the simulation apparatus further includes a fourth display control portion (7) which is configured to execute control for displaying the first chunk of the set chunks (sixteenth configuration).

Also, in the simulation apparatus of the sixth configuration, the simulation apparatus may further include a fifth display control portion (7) which is configured to execute control for displaying processing results of the window function process and the frequency analysis process, respectively, about one of the chunks, and
the model setting unit may be configured to be able to set the chunk that is redisplayed in terms of the processing results (seventeenth configuration).

Also, in the simulation apparatus of any one of the first to seventeenth configurations, the simulation apparatus may further include a sixth display control portion (7) which is so configured as to execute control for displaying, on the chunk-by-chunk basis, values of the loss function based on prediction results during training by the machine learning model (eighteenth configuration).

Also, in the simulation apparatus of any one of the first to eighteenth configurations, the simulation apparatus may further include a seventh display control portion (7) which is so configured as to execute control for displaying, on the chunk-by-chunk basis, values of the loss function based on prediction results by prediction after training by the machine learning model (nineteenth configuration).

Also, in the simulation apparatus of any one of the first to nineteenth configurations, time-series data of signals in normal status and anomaly status of a motor may be included in the data (twentieth configuration).

Also, in the simulation apparatus of any one of the first to twentieth configurations, the model computing unit may be configured to be able to use the machine learning model which has been non-temporarily stored by the model storage unit, and which has been subjected to execution of at least part of the computations of training (twenty-first configuration).

Also, in the simulation apparatus of any one of the first to twenty-first configurations, the simulation apparatus may further include an eighth display control portion (7) configured to execute control for displaying, in a matrix form, part of contents of the machine learning model which has been non-temporarily stored by the model storage unit and which has been subjected to execution of at least part of the computations of training (twenty-second configuration).

Also, in the simulation apparatus of the twenty-second configuration, the eighth display control portion may be configured to execute control for displaying, in a matrix form, information related to a weight that couples a hidden layer and an output layer to each other in the machine learning model which has been non-temporarily stored by the model storage unit and which has been subjected to execution of at least part of the computations of training (twenty-third configuration).

Also, in the simulation apparatus of any one of the first to twenty-third configurations, the model computing unit may be configured to be able to execute only the computations of prediction without executing the computations of training in a case where the machine learning model which has been non-temporarily stored by the model storage unit and which has been subjected to execution of at least part of the computations of training is used (twenty-fourth configuration).

Also, a program (P) according to one aspect of the present disclosure instructs a computer (100) to execute:
a first step of loading data;
a second step of executing setting related to a chunk as a batch block of data in a case where data are sequentially entered into a machine learning model on a basis of the loaded data;
a third step of executing computations of unsupervised training and computations of prediction by sequentially entering the chunk into the machine learning model; and
a fourth step in which the machine learning model having been subjected to execution of at least part of the computations of unsupervised training is non-temporarily stored in the recording medium.

Also, a simulation method according to one aspect of the disclosure comprises:
a first step of loading data;
a second step of executing setting related to a chunk as a batch block of data in a case where data are sequentially entered into a machine learning model on a basis of the loaded data;
a third step of executing computations of unsupervised training and computations of prediction by sequentially entering the chunk into the machine learning model; and
a fourth step in which the machine learning model having been subjected to execution of at least part of the computations of unsupervised training is non-temporarily stored in a recording medium.

The present disclosure is utilizable for, for example, simulations of unsupervised training in various fields.

What is claimed is:

1. A simulation apparatus comprising:
a model storage unit in which a machine learning model configured to execute training and prediction has been stored;
a model computing unit configured to execute computing process by using the machine learning model;
an operation input portion;
a loading unit configured to load data; and
a model setting unit configured to execute setting related to the machine learning model on a basis of input by the operation input portion,
wherein
the model setting unit is configured to, on a basis of the loaded data, execute setting related to a chunk as a batch block of data in a case where data are sequentially entered into the machine learning model,
the model computing unit is configured to execute computations of unsupervised training and computations of prediction by sequentially entering the chunk into the machine learning model, and
the model storage unit is configured to non-temporarily store not only the machine learning model before execution of the computations of training but also the machine learning model after execution of at least part of the computations of training.

2. The simulation apparatus as claimed in claim 1, wherein
the model computing unit is configured to be able to use the machine learning model which has been non-temporarily stored by the model storage unit and which has been subjected to execution of at least part of the computations of training.

3. The simulation apparatus as claimed in claim 1, further comprising:
a display control portion configured to execute control for displaying, in a matrix form, part of contents of the machine learning model which has been non-temporarily stored by the model storage unit and which has been subjected to execution of at least part of the computations of training.

4. The simulation apparatus as claimed in claim 3, wherein
the display control portion is configured to execute control for displaying, in a matrix form, information related to a weight that couples a hidden layer and an output layer to each other in the machine learning model which has been non-temporarily stored by the model storage unit and which has been subjected to execution of at least part of the computations of training.

5. The simulation apparatus as claimed in claim 1, wherein
the model computing unit is configured to be able to execute only the computations of prediction without executing the computations of training in a case where the machine learning model which has been non-temporarily stored by the model storage unit and which has been subjected to execution of at least part of the computations of training is used.

6. A recording medium with a program recorded therein, wherein
the program instructs a computer to execute:
a first step of loading data;
a second step of executing setting related to a chunk as a batch block of data in a case where data are sequentially entered into a machine learning model on a basis of the loaded data;
a third step of executing computations of unsupervised training and computations of prediction by sequentially entering the chunk into the machine learning model; and
a fourth step in which the machine learning model having been subjected to execution of at least part of the computations of unsupervised training is non-temporarily stored in the recording medium.

7. A simulation method comprising:
a first step of loading data;
a second step of executing setting related to a chunk as a batch block of data in a case where data are sequentially entered into a machine learning model on a basis of the loaded data;
a third step of executing computations of unsupervised training and computations of prediction by sequentially entering the chunk into the machine learning model; and
a fourth step in which the machine learning model having been subjected to execution of at least part of the computations of unsupervised training is non-temporarily stored in a recording medium.
